(19) United States
(12) Patent Application Publication
(10) Pub. No.: US 2023/0259018 A1
(43) Pub. Date: Aug. 17, 2023

(54) MASK AND METHOD FOR MANUFACTURING THE SAME

(71) Applicant: Samsung Display Co., Ltd., Yongin-si (KR)

(72) Inventors: SEIL KIM, Hwaseong-si (KR); SANG MIN YI, Seoul (KR)

(21) Appl. No.: 18/057,693

(22) Filed: Nov. 21, 2022

(30) Foreign Application Priority Data
Feb. 15, 2022 (KR) 10-2022-0019773

(51) Int. Cl. G03F 1/42

(52) U.S. Cl. CPC G03F 1/42

(57) ABSTRACT

A mask includes: a body having a length in a first direction and including: a plurality of first cell areas arranged in the first direction and respectively including a plurality of first holes; and a plurality of second cell areas respectively including a plurality of second holes; and a clamping part protruding from the body in the first direction and being integral with the body. An alignment mark is defined on the body and is offset from the first holes and the second holes, and the alignment mark overlaps the first and second cell areas when viewed in a second direction crossing the first direction.

### CROSS-REFERENCE TO RELATED APPLICATION

This application claims priority to and the benefit of Korean Patent Application No. 10-2022-0019773, filed on Feb. 15, 2022, in the Korean Intellectual Property Office (KIP), the entire contents of which are hereby incorporated by reference.

### BACKGROUND

### 1. Field

Aspects of embodiments of the present disclosure relate to a mask and a method for manufacturing the same.

### 2. Description of the Related Art

A display panel includes a plurality of pixels. Each of the pixels includes a driving element, such as a transistor, and a display element, such as an organic light emitting diode. The display element may be formed by laminating an electrode and an emission pattern on a substrate.

The emission pattern is patterned by using a mask in which openings (or holes) are defined to be formed in an area (e.g., in a predetermined area). The emission pattern may be formed on an area exposed by an opening. A shape of the emission pattern may be controlled according to a shape of the opening.

### SUMMARY

Embodiments of the present disclosure provide a mask for improving productivity of a display device and a method for manufacturing the same.

An embodiment of the present disclosure provides a mask including: a body having a length in a first direction and including: a plurality of first cell areas arranged in the first direction and respectively including a plurality of first holes; and a plurality of second cell areas respectively including a plurality of second holes; and a clamping part protruding from the body in the first direction and being integral with the body. An alignment mark is defined on the body and is offset from the first holes and the second holes, and the alignment mark overlaps the first and second cell areas when viewed in a second direction crossing the first direction.

The alignment mark may be a hole or a recess.

The alignment mark may include a photoresist.

The alignment mark may include a plurality of marks arranged in the first direction.

The alignment mark may include a first alignment mark and a second alignment mark spaced apart from each other in the second direction with the first holes and the second holes therebetween. Each of the first and second alignment marks may include the marks, and the marks of each of the first and second alignment marks may be aligned with each other in the second direction.

Each of the marks may have a circular, oval, or cross shape on a plane.

The alignment mark may include a first alignment mark and a second alignment mark spaced apart from each other in the second direction with the first holes and the second holes therebetween. Each of the first and second alignment marks may have a bar shape extending in the first direction, and the marks of each of the first and second alignment marks may be aligned with each other in the second direction.

A length of each of the first and second alignment marks in the first direction may be greater than a distance between adjacent cell areas of the first and second cell areas.

The body may include: a first body on which the first cell areas are defined; and a second body on which the second cell areas are defined. The alignment mark may be provided in plurality, and the plurality of alignment marks may be respectively defined on the first body and the second body to overlap each other on a plane.

The mask may further include a welding part configured to couple the first body to the second body.

The welding part may overlap the alignment mark on the plane.

The first body and the second body may be engaged with each other in the first direction.

The alignment mark may be on an area on which the first cell areas and the second cell areas are adjacent to each other, and the number of first cell areas and the number of second cell areas may be the same.

The alignment mark may be on an area on which the first cell areas and the second cell areas are adjacent to each other, and the number of first cell areas and the number of second cell areas may be different from each other.

The number of first cell areas may be greater than that of second cell areas.

According to another embodiment of the present disclosure, a method for manufacturing a mask includes: arranging a mask sheet including a pattern area, on which a first area and a second area are defined, on a first roller and a second roller; allowing the first roller and the second roller to rotate so that the pattern area is on an exposure module; performing, through the exposure module, a first exposure process on the first area to form a first pattern and an alignment mark on the first area; aligning the exposure module with the second area through the alignment mark; and performing, through the exposure module, a second exposure process on the second area to form a second pattern on the second area.

The first area and the second area may partially overlap each other, and the alignment mark may be formed on an area on which the first area and the second area overlap each other.

The first pattern and the alignment mark may be concurrently formed by one photomask.

In the aligning of the exposure module, the first area and the second area may be aligned with each other in a first direction by using the alignment mark.

A length of the first area and a length of the second area in the first direction may be substantially the same.

The mask sheet may further include a third area spaced apart from the second area and partially overlapping the first area, and the method may further include performing, through the exposure module, a third exposure process on the third area to form a third pattern on the third area. A length of the first area in a first direction may be greater than that of second area or the third area in the first direction.

The method of may further include, before the forming of the third pattern on the third area, aligning the exposure module with the third area. The alignment mark may include: a first alignment mark formed on an area of the first area that overlaps the second area; and a second alignment mark formed on an area of the first area that overlaps the third area.

The alignment mark may include one of a plurality of circular patterns arranged in a first direction, a plurality cross-shaped patterns, and a bar-shaped pattern extending in the first direction.

### BRIEF DESCRIPTION OF THE DRAWINGS

The accompanying drawings are included to provide a further understanding of the present disclosure and are incorporated in and constitute a part of this specification. The drawings illustrate embodiments of the present disclosure and, together with the description, explain aspects and features of the present disclosure. In the drawings:

FIG. 1 is an example of a mask assembly according to an embodiment of the present disclosure;

FIG. 2 is a perspective view of the mask illustrated in FIG. 1;

FIGS. 3A to 3E are views of masks according to embodiments of the present disclosure;

FIG. 4 is a view of an example of a step of manufacturing a display device using a mask according to an embodiment of the present disclosure;

FIG. 5 is a flowchart describing a method for manufacturing a mask according to an embodiment of the present disclosure;

FIG. 6 is a schematic view of an overall configuration of a system for performing an exposure process in processes of manufacturing the mask according to an embodiment of the present disclosure;

FIG. 7 is a view of an example of a shape of a mask sheet illustrated in FIG. 6;

FIGS. 8A to 8I are schematic views of steps of manufacturing the mask according to an embodiment of the present disclosure;

FIGS. 9A to 9C are plan views of exposure alignment holes according to embodiments of the present disclosure;

FIG. 10 is a perspective view of a mask according to an embodiment of the present disclosure;

FIGS. 11A to 11D are views showing steps of manufacturing the mask illustrated in FIG. 10;

FIGS. 12A to 12D are views showing steps of manufacturing the mask illustrated in FIG. 10;

FIGS. 13A and 13B are views showing a mask according to an embodiment of the present disclosure;

FIGS. 14A and 14B are views showing a mask according to an embodiment of the present disclosure; and

FIGS. 15A to 15C are views showing a mask according to an embodiment of the present disclosure.

### DETAILED DESCRIPTION

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of,” when preceding a list of elements, modify the entire list of elements and do not modify the individual elements of the list. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Hereinafter, embodiments of the present disclosure will be described with reference to the accompanying drawings.

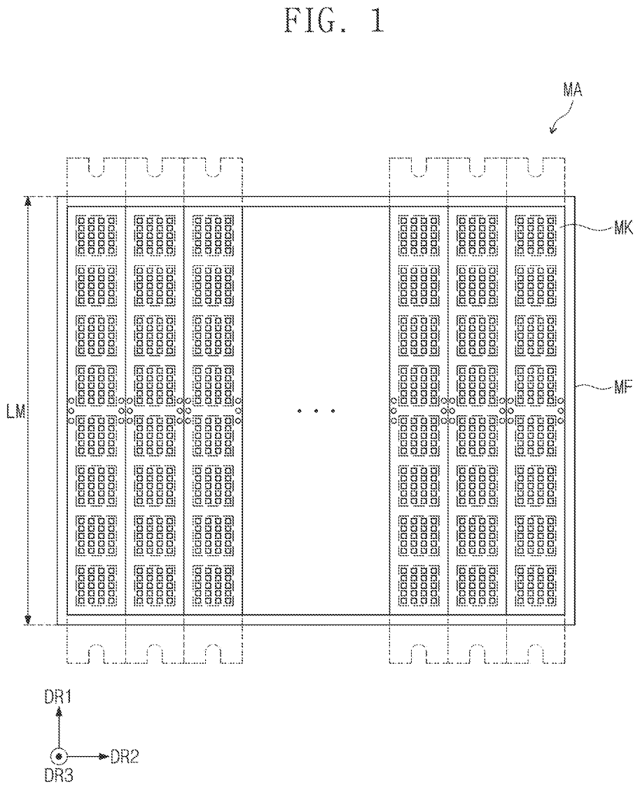

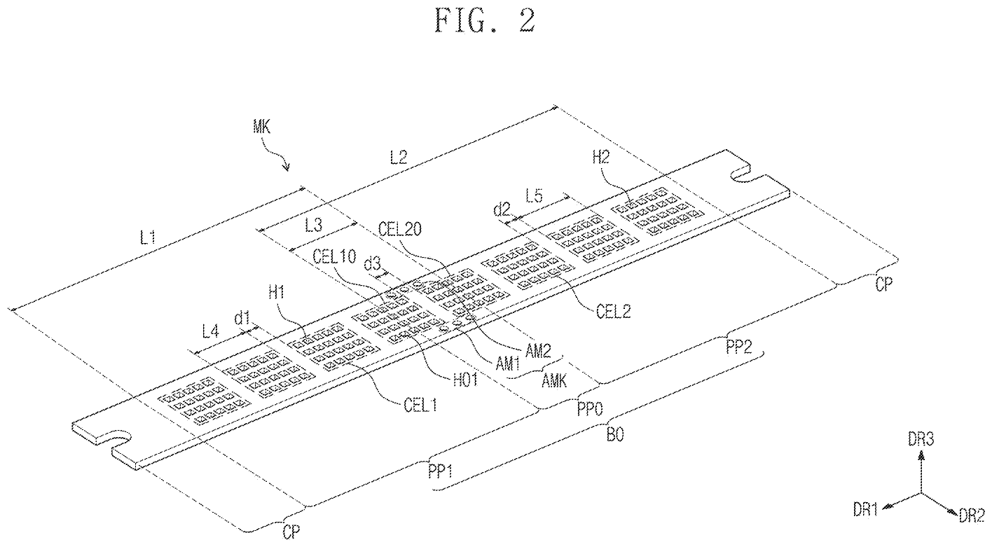

FIG. 1 is a view of an example of a mask assembly according to an embodiment of the present disclosure, and FIG. 2 is a perspective view of the mask illustrated in FIG. 1.

A mask assembly MA may be used in a process of manufacturing a display device. For example, the mask assembly MA may be used in a process of depositing an organic light emitting element layer on a deposition substrate of a display device.

Referring to FIGS. 1 and 2, the mask assembly MA may include a plurality of masks MK and a mask frame MF. The mask assembly MA may have a rectangular shape with sides extending in a first direction DR1 and sides extending in a second direction DR2. However, the present disclosure is not limited thereto, and the mask assembly MA may have various shapes corresponding to a shape of the display device.

Hereinafter, a direction that substantially perpendicularly intersects a plane defined by the first direction DR1 and the second direction DR2 is defined as a third direction DR3. In the present specification, the meaning of “viewed on a plane” may refer to a view in the third direction DR3.

The mask frame MF may have a rectangular closed line shape when viewed in a plan view. For example, the mask frame MF may include two frames extending in the first direction DR1 and two frames extending in the second direction DR2. An opening may be defined at a center of the mask frame MF when the frames are connected.

The mask frame MF may have sufficient rigidity. To this end, the mask frame MF may include a metal material, such as stainless steel (SUS), a nickel-rion alloy (e.g., an Invar alloy), nickel (Ni), or cobalt (Co).

Masks MK may be fixed to the mask frame MF. For example, the masks MK may be fixed to the mask frame MF in a state in which the masks are arranged in (e.g., are adjacent to each other in) the second direction DR2. Each of the masks MK may extend in the first direction DR1. In this embodiment, a length LM of the mask frame MF (e.g., a mask frame length) in the first direction DR1 may be about 1,200 mm or more. Thus, the length of the mask MK in the first direction DR1 may be equal to or greater than the mask frame length LM. For example, each of the length of the mask frame LM and the length of the mask MK in the first direction DR1 may be about 2,000 mm or more. According to embodiments of the present disclosure, an integrated mask MK having a length of about 1,200 mm or more may be easily provided, and thus, a large-area display device may be provided, and a large-area mask assembly MA configured for depositing a relatively great number of cell areas may be provided. The length LM of the mask frame may be about 1,200 mm or less and is not, however, limited.

The mask MK may include a body BO, a clamping part CP, a plurality of first cell areas CEL1, and a plurality of second cell areas CEL2.

The body BO may have long sides extending in the first direction DR1 and short sides extending in the second direction DR2. When viewed in the plan view, the body BO may have a rectangular shape extending lengthwise in (e.g., extending primarily in) the first direction DR1. The clamping part CP may extend from the short sides of the body BO in the first direction DR1. The clamping part CP may be removed after the body BO is fixed to the mask frame MF.

According to an embodiment of the present disclosure, the body BO may have a first portion PP1, a second portion PP2, and an overlapping portion PP0. The overlapping portion PP0 may be disposed between the first portion PP1 and the second portion PP2. The first portion PP1, the overlapping portion PP0, and the second portion PP2 may be sequentially arranged in the first direction DR1.

The sum of the length of the first portion PP1 and the length of the overlapping portion PP0 in the first direction DR1 may be a first length L1. The sum of the length of the second portion PP2 and the length of the overlapping portion PP0 in the first direction DR1 may be a second length L2. The length of the overlapping portion PP0 in the first direction DR1 may be a third length L3.

The plurality of cell areas CEL1 and CEL2 may include a plurality of first cell areas CEL1 and a plurality of second cell areas CEL2.

The first cell areas CEL1 may be defined on a portion of the first portion PP1 and the overlapping portion PP0. When viewed in the plan view, each of the first cell areas CEL1 may have a rectangular shape. A length of each of the first cell areas CEL1 in the first direction DR1 may be a fourth length L4. The fourth length L4 may be less than the first length L1. A surface area of the first cell area CEL1 may substantially correspond to a surface area of one display device.

In FIG. 2, four first cell areas CEL1 are illustrated as being defined on the first portion PP1, but this is only for convenience of description and the number of first cell areas CEL1 is limited thereto. In other embodiments, the number of first cell areas CEL1 defined on the first portion PP1 may be greater than four.

The first cell areas CEL1 may be spaced apart from each other in the first direction DR1. For example, a distance between the first cell areas CEL1 adjacent to each other in the first direction DR1 may be a first distance d1. A plurality of first holes (or first openings) H1 spaced apart from each other may be defined in each of the first cell areas CEL1. The first distance d1 may be equal to or greater than a distance between the first holes H1 in the first cell areas CEL1. When viewed in the plan view, each of the first holes H1 may have a rectangular shape. The first holes H1 may pass through (or extend through) the body BO in a thickness direction (e.g., the third direction DR3).

In FIG. 2, twenty first holes H1 are defined in one first cell area CEL1, but the number of first holes H1 defined in one first cell area CEL1 may be greater than the number of first holes H1 shown in the one first cell area CEL1 in the drawings. Also, the shape of each of the first holes H1 is not limited to the rectangular shape, and the shape of each of the first holes H1 may be variously changed.

The first cell area CEL10 of the first cell areas CEL1 that is adjacent to the second cell areas CEL2 may be defined over the first portion PP1 and the overlapping portion PP0. For example, a portion of the first cell area CEL10 may be defined on the first portion PP1, and the remaining portion of the first cell area CEL10 may be defined on the overlapping portion PP0.

The second cell areas CEL2 may be defined on a portion of the second portion PP2 and the overlapping portion PP0. When viewed in the plan view, each of the second cell areas CEL2 may have a rectangular shape. A length of each of the second cell areas CEL2 in the first direction DR1 may be a fifth length L5. In the illustrated embodiment, the fifth length L5 may be the same as the fourth length L4.

The second cell areas CEL2 may be spaced apart from each other in the first direction DR1. For example, an interval between the adjacent second cell areas CEL1 may be a second distance d2. In the illustrated embodiment, the second distance d2 may be the same as the first distance d1. However, this is merely an example, and, in other embodiments, the second distance d2 may be different from the first distance d1.

A plurality of second holes (or second openings) H2 may be defined in each of the second cell areas CEL2. The second distance d2 may be equal to or greater than a distance between the second holes H2 in the second cell areas CEL2. When viewed in the plan view, each of the second holes H2 may have a rectangular shape. The second holes H2 may pass through (or extend through) the body BO in a thickness direction (e.g., the third direction DR3). However, the shape of each of the second holes H2 is not limited thereto. The shape of each of the second holes H2 may be variously changed, such as a rhombus or a circle.

The second cell area CEL20 of the second cell areas CEL2 that is adjacent to the first cell areas CEL1 may be defined over the second portion PP2 and the overlapping portion PP0. For example, a portion of the second cell area CEL20 may be defined on the second portion PP2, and the remaining portion of the second cell area CEL20 may be defined on the overlapping portion PP0.

According to the illustrated embodiment, a portion of the first cell area CEL10 and a portion of the second cell area CEL20 may be defined on the overlapping portion PP0. This is merely an example, and only one cell area or three or more cell areas may be defined on the overlapping portion PP0 according to the arrangement and number of cell areas.

A distance between the first cell area CEL10 and the second cell area CEL20 may be a third distance d3. The third distance d3 may be the same as the first distance d1 or the second distance d2. However, this is merely an example, and the third distance d3 may be different from each of the first distance d1 and the second distance d2.

Dummy holes may be added between the first cell area CEL10 and the second cell area CEL20. Each of the dummy holes may have the same shape as or partially the same shape as each of the first hole H1 or the second hole H2. For example, the dummy holes may include four holes arranged in the second direction DR2.

The mask MK according to an embodiment of the present disclosure may include an alignment mark AMK. The alignment mark AMK may be defined on the overlapping portion PP0. The alignment mark AMK may include a plurality of first alignment marks AM1 and a plurality of second alignment marks AM2, which are disposed to be spaced apart from each other in the second direction DR2.

The first alignment marks AM1 and the second alignment marks AM2 may be disposed so as not to overlap (e.g., to be offset from) the cell areas CEL1 and CEL2 when viewed in the plan view. The first alignment marks AM1 and the second alignment marks AM2 may be disposed to be spaced apart from each other in the second direction DR2 with the overlapping first and second cell areas therebetween. The first alignment marks AM1 and the second alignment marks AM2 may be aligned at positions overlapping each other when viewed in the second direction DR2.

Each of the first alignment marks AM1 and the second alignment marks AM2 may be a hole (or opening) passing through the body BO or a recess part (or recess) defined by removing a portion of the body BO surface. In some embodiments, each of the first alignment marks AM1 and the second alignment marks AM2 may be a photoresist pattern disposed on the body BO. In the illustrated embodiment, each of the first alignment marks AM1 and the second alignment marks AM2 is illustrated as three circular holes arranged in the first direction DR1, but the present disclosure is not limited thereto. Each of the first alignment marks AM1 and the second alignment marks AM2 may be provided in various numbers and various shapes.

The mask MK according to the present disclosure may be formed through a plurality of exposure processes. For example, the first area AR1 and the second area AR2 may correspond to areas exposed at different timings. The plurality of alignment marks AM1 and AM2 may align the first area AR1 and the second area AR2 in the first direction DR1, and thus, the cell areas CEL1 and CEL2 may be aligned in the first direction DR1. Thus, even when one mask is formed through a plurality of exposure processes, the alignment of the cell areas CEL1 and CEL2 may be improved, and a defect rate of the mask MK may be reduced. In addition, because a greater number of cell areas may be secured in one mask, manufacturing efficiency of the display device may be improved.

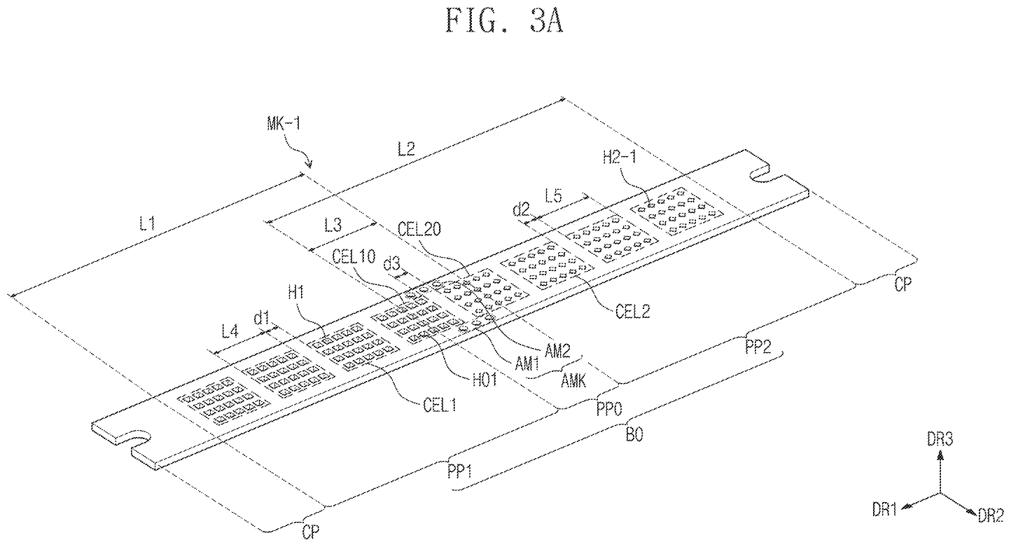

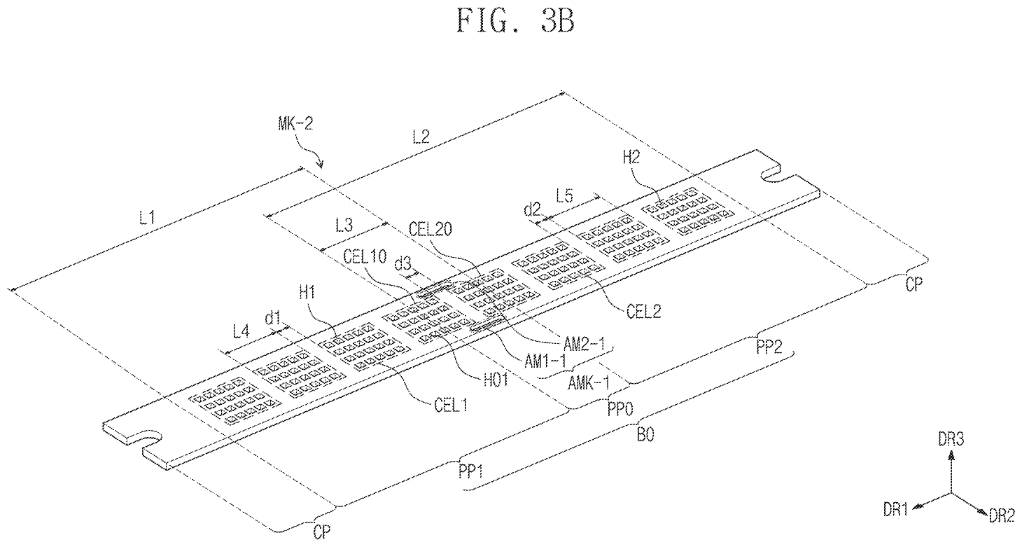

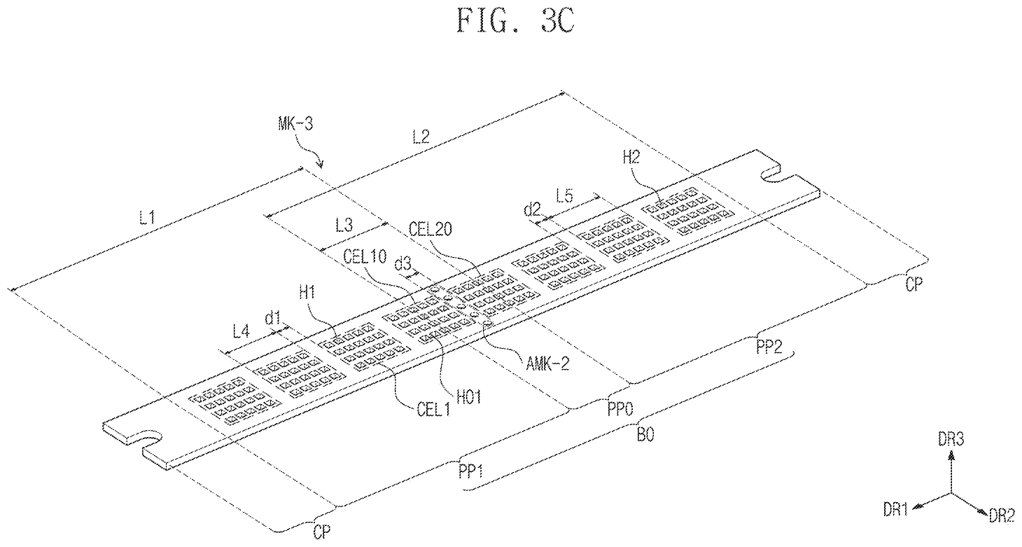

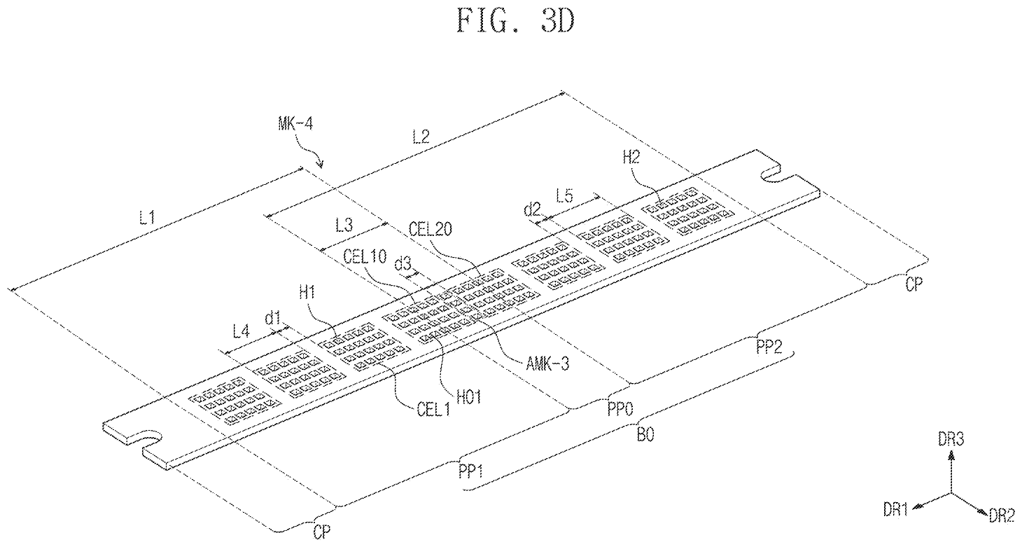

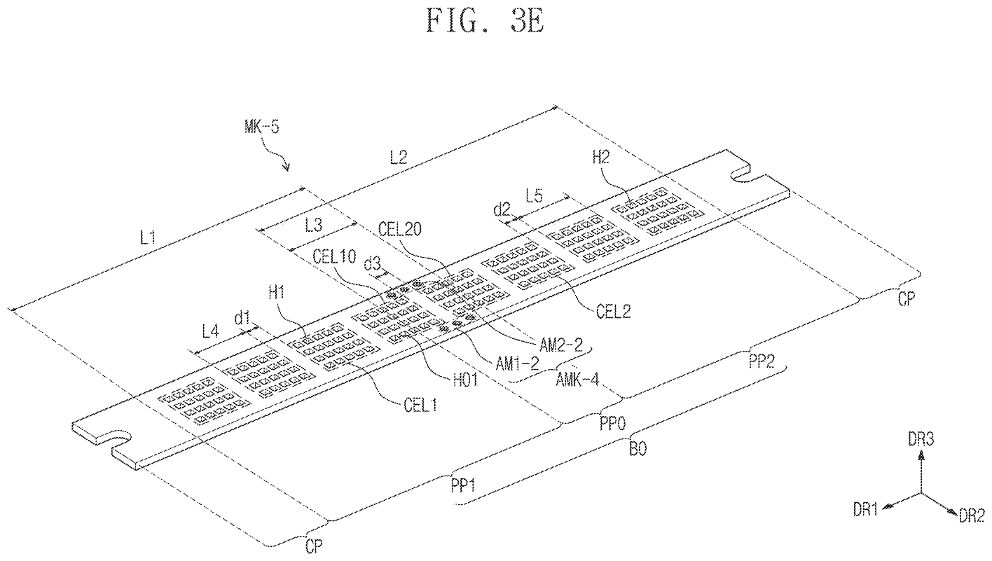

FIGS. 3A to 3E are views illustrating masks according to embodiments of the present disclosure. Hereinafter, embodiments of the present disclosure will be described with reference to FIGS. 3A to 3E.

Referring to FIG. 3A, in a mask MK-1, first holes H1 and a second holes H2-1 may have different shapes. For example, the second hole H2-1 defined in the second cell areas CEL2-1 may have a rhombus shape when viewed in the plan view. As a result, the first holes H1 and the second holes H2-1 having different shapes may be defined in one mask MK-1.

Also, holes H01 of a first overlapping cell area and holes H02-1 of second overlapping cell area may have different shapes. For example, each of the holes H01 of the first overlapping cell area has a shape corresponding to each of the first holes H1, and each of the holes H02-1 of the second overlapping cell area has a shape corresponding to each of the second holes H2-1. As a result, overlapping cell areas in which holes H01 and H02-1 having different shapes are defined may be defined in one mask MK-1.

Thus, display devices having different emission patterns may be manufactured using one mask MK-1. However, the shapes of the holes H1, H2-1, H01, and H02-1 are not limited thereto.

Referring to FIG. 3B, in a mask MK-2, an alignment mark AMK-1 includes a single first alignment mark AM1-1 and a single second alignment mark AM2-1, which are spaced apart from each other in the second direction DR2. Each of the alignment marks AM1-1 and AM2-1 may have a bar shape when viewed in the plan view. For example, each of the first and second alignment marks AM1-1 and AM2-1 has a straight bar shape extending in (e.g., primarily extending in) the first direction DR1 and parallel to each other in the second direction DR2. For example, in the illustrated embodiment, each of the first and second alignment marks AM1-1 and AM2-1 may be provided as one mark. As described above, each of the first and second alignment marks AM1-1 and AM2—may be provided as a hole passing through the body BO or a concave recess part.

Referring to FIG. 3C, in a mask MK-3, an alignment mark AMK-2 may include a plurality of marks arranged in the second direction DR2. As described above, each of the marks may be provided as a hole passing through the body BO or a concave recess part. The alignment mark AMK-2 may be defined between two adjacent cells CEL. Thus, a width of the mask MK-3 in the first direction DR1 may be reduced.

Referring to FIG. 3D, in a mask MK-4, an alignment mark AMK-3 may include a plurality of marks arranged in the second direction DR2. As described above, each of the marks may be provided as a hole passing through the body BO or a concave recess part. The alignment mark AMK-3 may be defined between two adjacent cells CEL.

In such an embodiment, the alignment mark AMK-3 may be provided as four marks, different from the alignment mark AMK-2 illustrated in FIG. 3C. The marks may be aligned with the first holes H1 or the second holes H2 in the first direction DR1. For example, the alignment marks AMK-3 may be arranged in a shape similar to that in which the first holes H1 and the second holes H2 are continuous (or are arranged). The four marks may have the same shape as the planar shape of the first holes H1 or the second holes H2. Alternatively, the four marks may have the same shape as a portion of the planar shape of the first holes H1 or the second holes H2.

Referring to FIG. 3E, in a mask MK-5, an alignment mark AMK-4 may include a plurality of marks AM1-2 and AM2-2 spaced apart from each other in the second direction DR2. Each of the marks AM1-2 and AM2-2 may include a plurality of marks arranged in the first direction DR1. Each of the marks AM1-2 and AM2-2 may have a cross shape on a plane defined by the first direction DR1 and the second direction DR2. The masks MK-1, MK-2, MK-3, MK-4, and MK-5 according to embodiments of the present disclosure may include various types of alignment marks, and are not limited to any one embodiment.

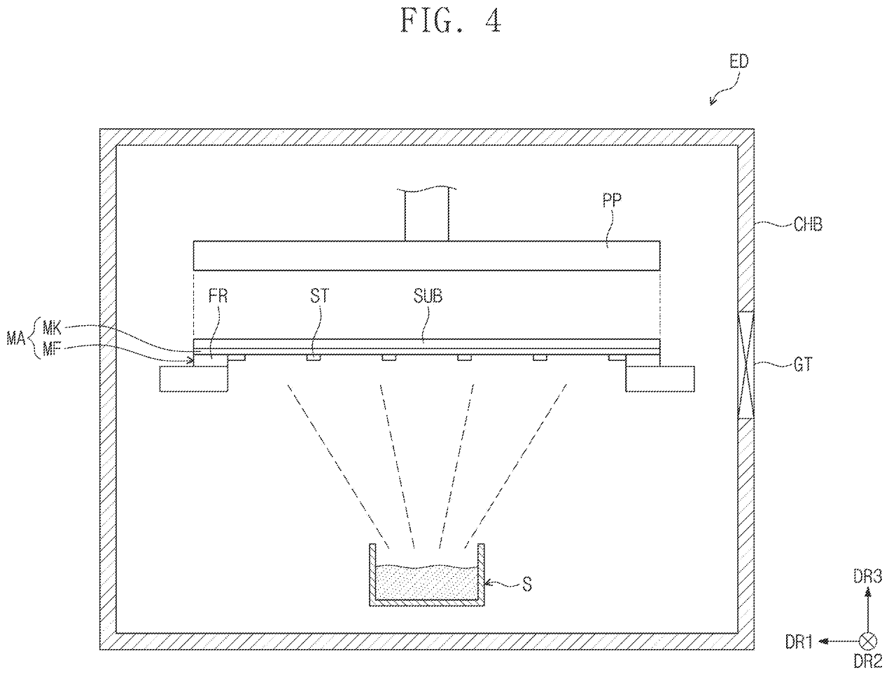

FIG. 4 is a view illustrating an example of a process of manufacturing a display device using a mask according to an embodiment of the present disclosure; Hereinafter, a process of depositing an organic light emitting diode on a substrate SUB of the display device using the above-described mask MK will be described.

Referring to FIG. 4, deposition equipment ED may include a chamber CHB, a deposition source S, a stage ST, a driving plate PP, and a mask assembly MA.

The evaporation source S, the stage ST, the driving plate PP, and the mask assembly MA may be disposed inside the chamber CHB. The chamber CHB may form a sealed space. The chamber CHB may include at least one gate GT. The chamber CHB may be opened and closed via the gate GT. The mask assembly MA and the substrate SUB may be accessible through the gate GT provided in the chamber CHB. The substrate SUB may be a base substrate on which a deposition material is to be deposited in the display device.

The deposition source S may be disposed in a lower portion of the chamber CHB. The deposition source S may include a deposition material. The deposition material may include one or more of an inorganic material, a metal, and an organic material as a material capable of sublimation or vaporization. In this embodiment, a case in which the deposition source S includes an organic material for manufacturing an organic light emitting element will be described as an example.

The stage ST may be disposed above the deposition source S. The mask assembly MA may be seated on the stage ST. The mask assembly MA may face the deposition source S. On the plane, the stage ST may overlap the mask frame MF to support the mask assembly MA. The stage ST may be disposed outside a moving path of the deposition material supplied from the deposition source S to the substrate SUB.

The substrate SUB may be disposed on the mask assembly MA. The driving plate PP may be disposed on the substrate SUB. The driving plate PP may align the substrate SUB on the mask assembly MA.

The deposition material may be deposited on the substrate SUB through the first holes H1 and the second holes H2 of the mask MK illustrated in, for example, FIG. 2. As a result, the organic light emitting diode may be deposited on the substrate SUB through the mask assembly MA.

Hereinafter, a method for manufacturing a mask according to an embodiment of the present disclosure will be described.

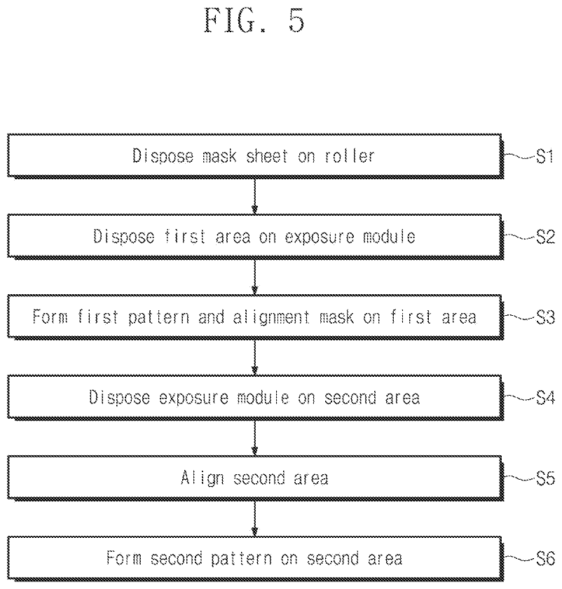

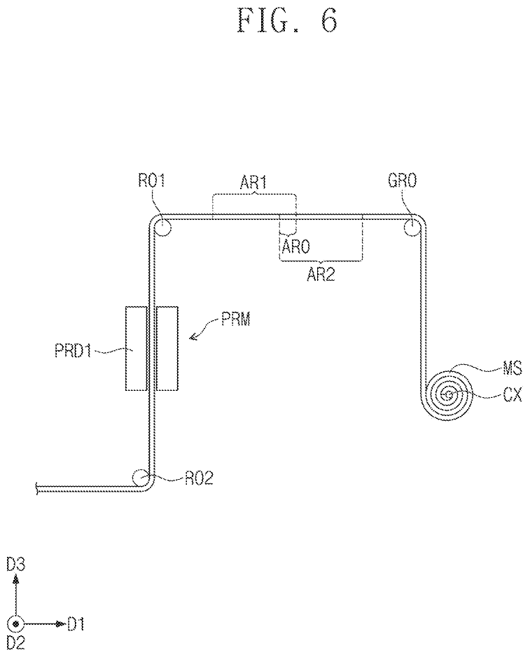

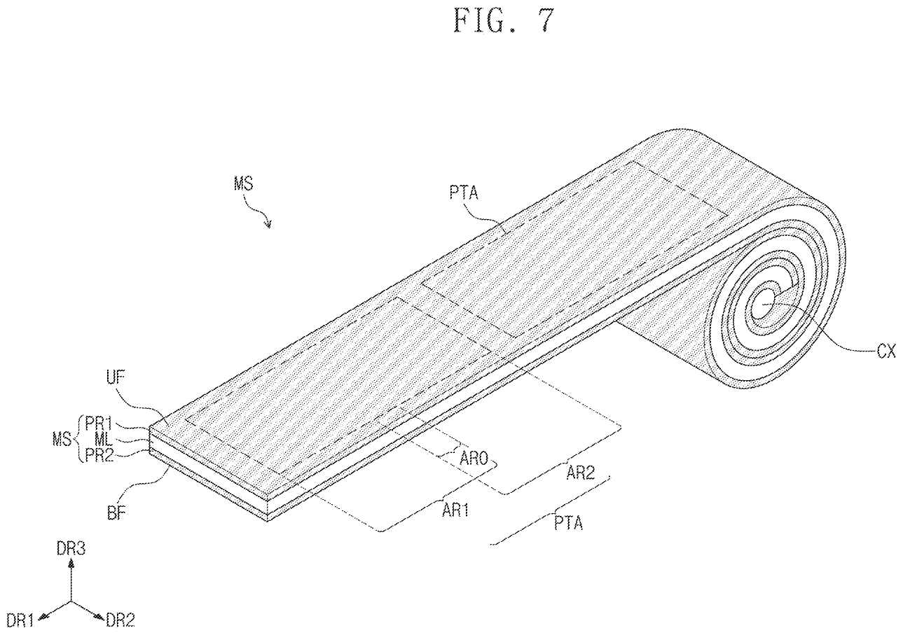

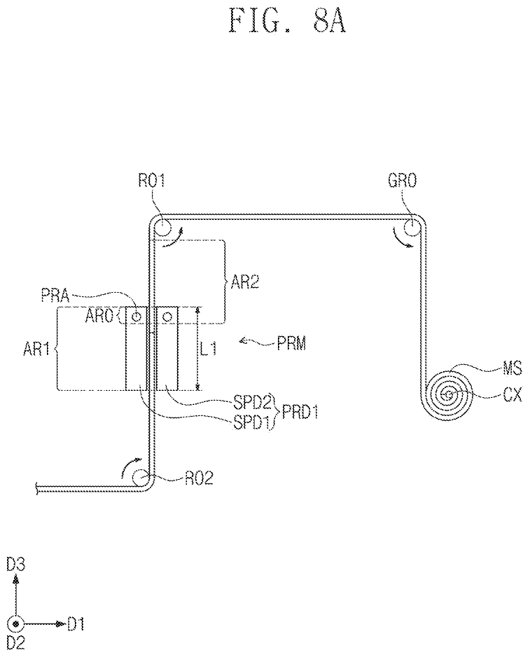

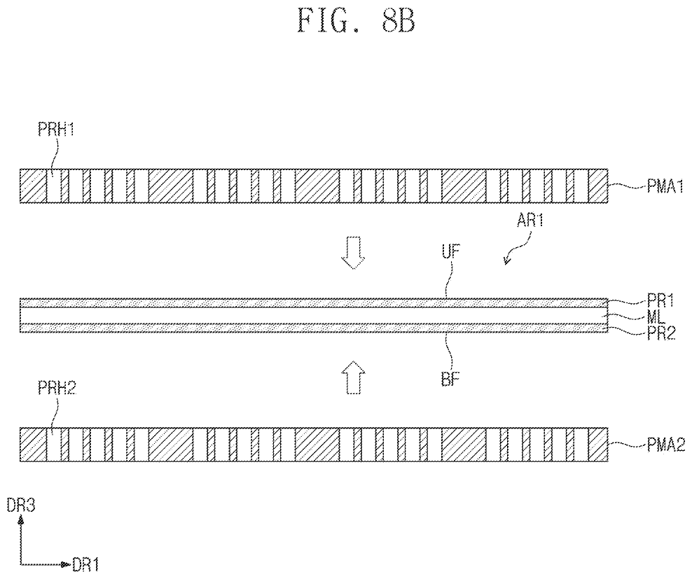

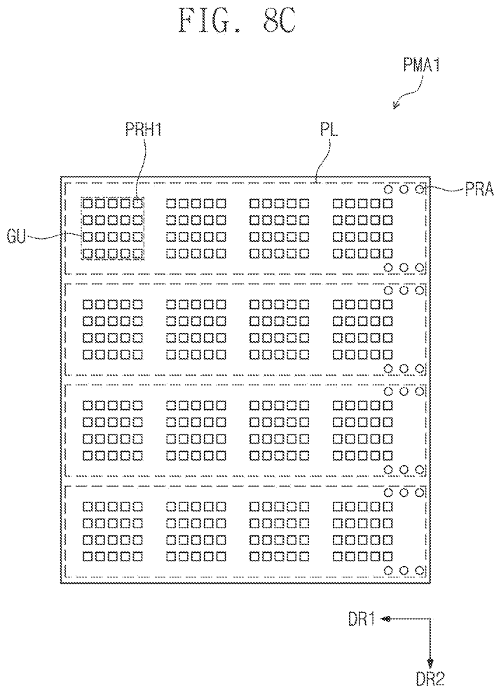

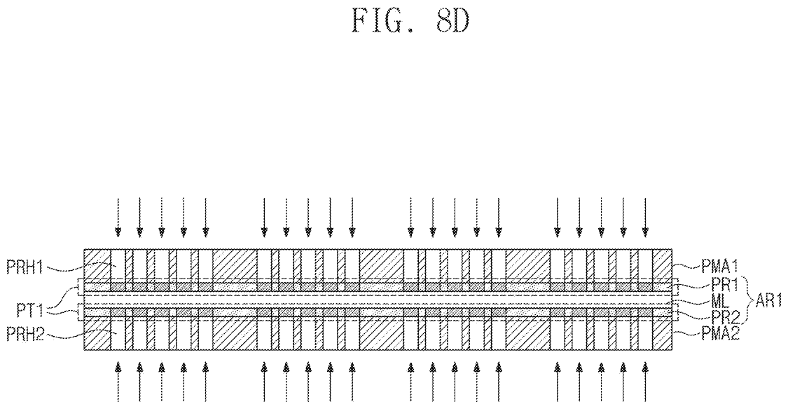

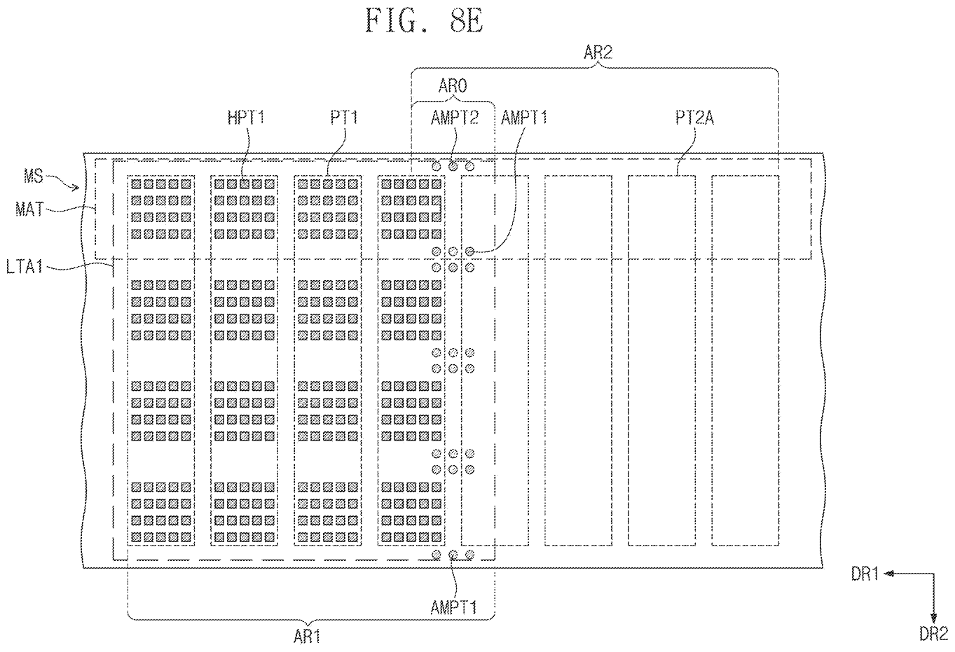

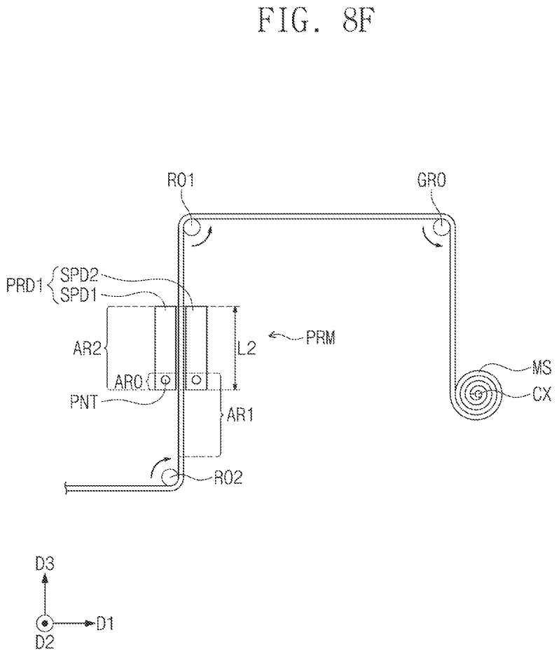

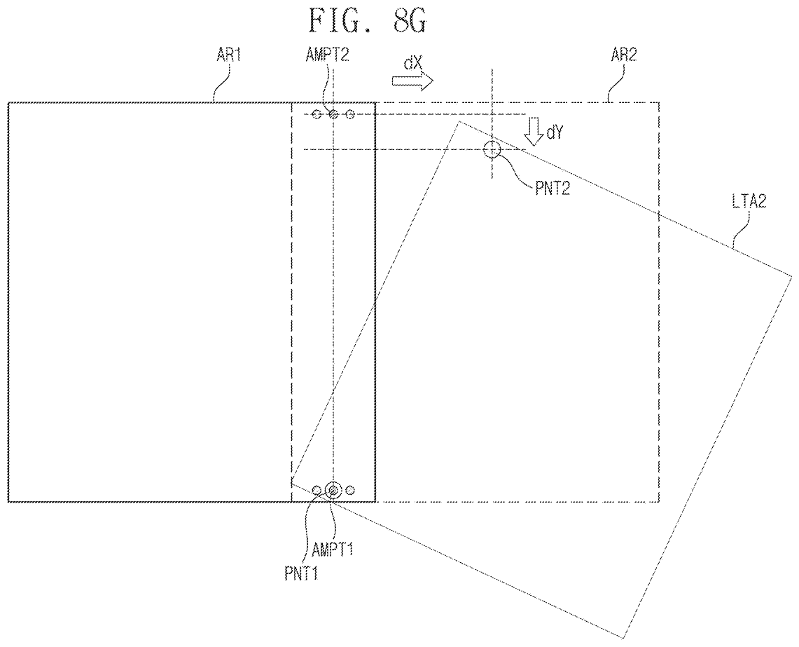

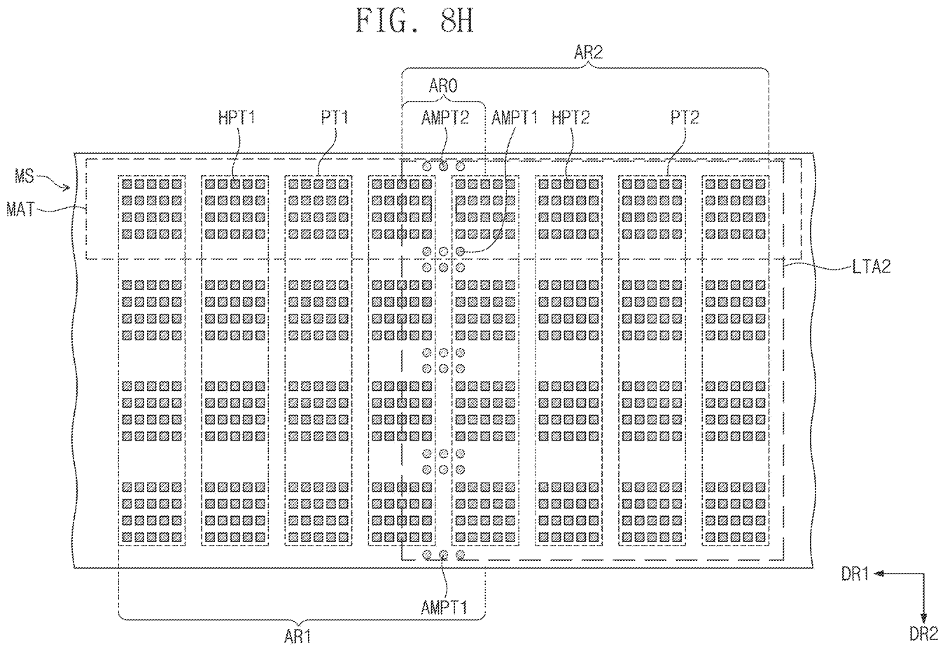

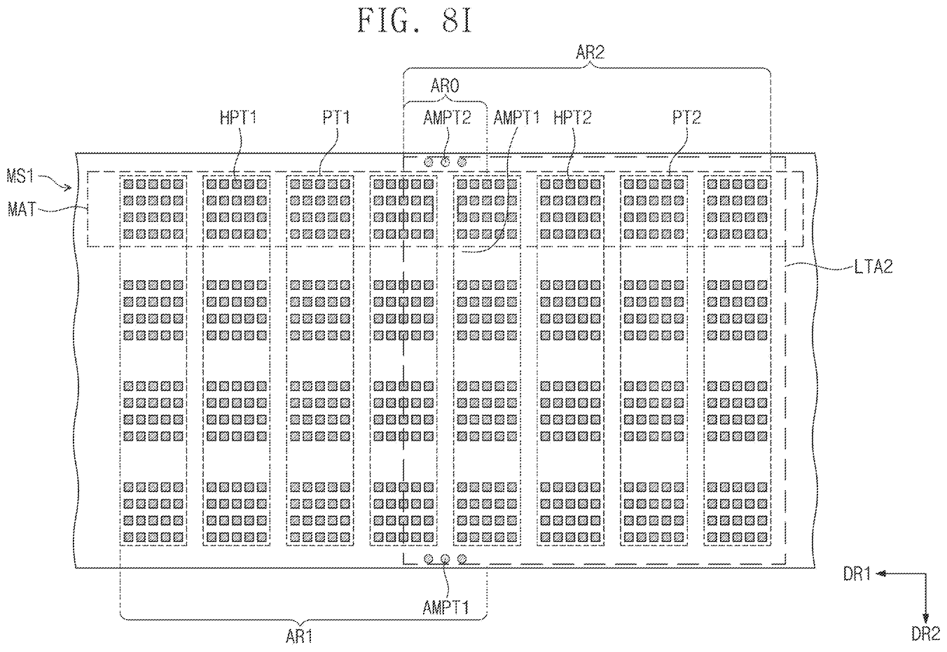

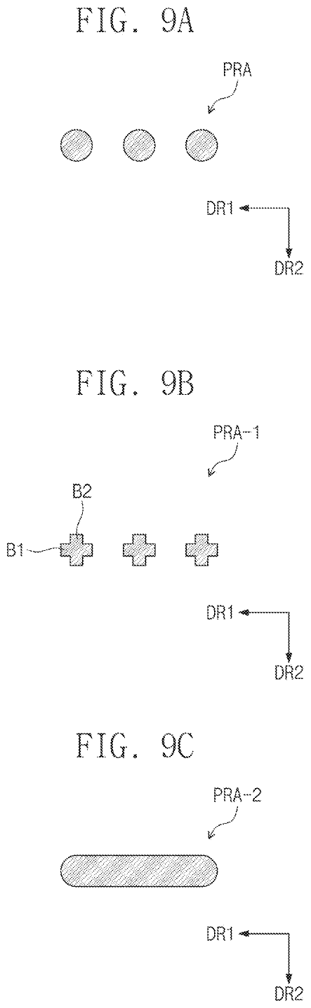

FIG. 5 is a flowchart illustrating steps of a method for manufacturing the mask according to an embodiment of the present disclosure. FIG. 6 is a schematic view illustrating an overall configuration of a system that performs an exposure process in processes of manufacturing the mask according to an embodiment of the present disclosure. FIG. 7 is a view illustrating an example of a shape of a mask sheet illustrated in FIG. 6. FIGS. 8A to 8F are schematic views illustrating processes of manufacturing the mask according to an embodiment of the present disclosure. FIGS. 9A to 9C are plan views illustrating exposure alignment holes according to embodiments of the present disclosure. Hereinafter, embodiments of the present disclosure will be described with reference to FIGS. 5 to 9C.

Referring to FIGS. 5 to 7, in a first process S1, a mask sheet MS may be disposed on a first roller RO1 and a second roller RO2. The mask sheet MS may have a sheet shape having a thin thickness in the third direction DR3. The mask sheet MS may be flexible. For example, the mask sheet MS may be wound or unwound based on (e.g., about) the central axis CX. The central axis CX may be parallel to the second direction DR2 (e.g., a width direction of the mask sheet MS and may be perpendicular to the first direction DR1, such as a longitudinal direction of the mask sheet MS). The second directional axis D2 illustrated in FIG. 6 may correspond to the width direction of the mask sheet MS and an extension direction of the central axis CX. The third directional axis D3 may correspond to a direction opposite to gravity. A first directional axis D1 may be a direction perpendicular to each of the second directional axis D2 and the third directional axis D3.

The mask sheet MS may include a first photoresist PR1, a metal layer ML, and a second photoresist PR2. For example, the first photoresist PR1 may be disposed on a top surface of the metal layer ML, and the second photoresist PR2 may be disposed on a bottom surface of the metal layer ML. Each of the first photoresist PR1 and the second photoresist PR2 may include a positive photosensitive material. However, the materials of the first photoresist PR1 and the second photoresist PR2 are not limited thereto. For example, the first and second photoresists PR1 and PR2 may include a negative photosensitive resist material. Patterns may be formed on each of the first photoresist PR1 and the second photoresist PR2 by exposure processes to be described later.

The metal layer ML may be sufficiently rigid. The metal layer ML may have (or may be) the same or substantially the same material as the mask MK illustrated in, for example, FIG. 2. For example, the metal layer ML may include a metal material, such as an Invar alloy.

The mask sheet MS may have a top surface UF and a bottom surface BF. For example, as illustrated in FIG. 7, the top surface UF and the bottom surface BF may be defined by the first direction DR1 and the second direction DR2. The top surface UF of the mask sheet MS may refer to a top surface of the first photoresist PR1, and the bottom surface BF may refer to a bottom surface of the second photoresist PR2.

The mask sheet MS may include a plurality of pattern areas PTA. A length of each of the pattern areas PTA in the first direction DR1 may correspond to a length of the body BO of the mask MK illustrated in, for example, FIG. 2 in the first direction DR1. For example, a first area AR1, a second area AR2, and an overlapping area AR0 may be defined on each of the pattern areas PTA. The overlapping area AR0 may be an area at where the first area AR1 and the second area AR2 overlap each other.

The first area AR1 may be an area exposed by an exposure machine to form the first cell areas CEL1 (see, e.g., FIG. 2). For example, the first area AR1 may correspond to an area including the first portion PP1 (see, e.g., FIG. 2) and the overlapping portion PP0 (see, e.g., FIG. 2). Thus, a length of the first area AR1 may be the same as the first length L1 (see, e.g., FIG. 2), which is the sum of the lengths of the first portion PP1 and the overlapping portion PP0 in the first direction DR1.

The second area AR2 may be an area exposed by an exposure machine to form the second cell areas CEL2 (see, e.g., FIG. 2). For example, the second area AR2 may correspond to an area including the second portion PP2 (see, e.g., FIG. 2) and the overlapping portion PP0. Thus, a length of the second area AR2 may be the same as the second length L2 (see, e.g., FIG. 2), which is the sum of the lengths of the second portion PP2 and the overlapping portion PP0 in the first direction DR1.

However, the length of the first area AR1 may be greater than the first length L1 in the first direction DR1. Similarly, the length of the second area AR2 may be greater than the second length L2. The third area AR3 may have the same length as the third length L3 (see, e.g., FIG. 2) in the first direction DR1.

The mask sheet MS may be moved by the first roller RO1 and the second roller RO2. The first roller RO1 may be spaced apart from the second roller RO2. For example, the first roller RO1 may be disposed at a position higher than that of the second roller RO2 with respect to the third directional axis D3. Each of the first roller RO1 and the second roller RO2 may be in contact with the mask sheet MS. For example, the first roller RO1 may be in contact with a portion of the bottom surface BF of the mask sheet MS, and the second roller RO2 may be in contact with a portion of the top surface UF of the mask sheet MS.

An exposure module PRM may be disposed between the first roller RO1 and the second roller RO2. The exposure module PRM may include at least one exposure machine. For example, the exposure module PRM may include a first exposure machine PRD1. The first exposure machine PRD1 may perform an exposure process on (e.g., may expose) at least one surface of the mask sheet MS. Details of the first exposure machine PRD1 will be described later.

According to an embodiment of the present disclosure, a guide roller GRO may be further disposed between the first roller RO1 and a central axis CX on which the mask sheet MS is wound. The guide roller GRO may be disposed at the same height as the first roller RO1 with respect to the third directional axis D3. The guide roller GRO may guide the unwound mask sheet MS from the central axis CX to the first roller RO1.

FIG. 8A is a view describing a second process (S2) illustrated FIG. 5. Referring to FIGS. 5 and 8A, in the second process (S2), the pattern area PTA may be disposed on (or in) the exposure module PRM. Here, the mask sheet MS may be moved as the first roller RO1 and the second roller RO2 rotate. The first roller RO1 may rotate in a counterclockwise direction with respect to the second directional axis D2, and the second roller RO2 may rotate in a clockwise direction. Frictional force may act between the first and second rollers RO1 and RO2 and the mask sheet MS. Thus, the mask sheet MS may be unwound to move from the first roller RO1 toward the second roller RO2.

When the first area AR1 of the pattern area PTA is disposed on (e.g., is in or aligned with) the first exposure machine PRD1, the first roller RO1 and the second roller RO2 may be stopped (e.g., the first roller RO1 and the second roller RO2 may be stopped from rotating). Here, the third area AR3 and the second area AR2 may be disposed between the first exposure machine PRD1 and the first roller RO1 or near the first roller RO1. The first roller RO1 and the second roller RO2 are disposed to be spaced apart from each other along the third directional axis D3, and, at this step, the first area AR1 of the mask sheet MS is disposed between the first roller RO1 and the second roller RO1. Thus, a portion of the mask sheet MS including the first area AR1 may be disposed to be parallel to a plane defined by the second directional axis DR2 and the third directional axis DR3.

The rotation directions of the first roller RO1 and the second roller RO2 are not limited to the above-described directions. For example, the first roller RO1 may rotate in the clockwise direction, and the second roller RO2 may rotate in the counterclockwise direction to wind the mask sheet MS.

FIGS. 8B to 8E are views describing a third process (S3) as illustrated FIG. 5. Referring to FIGS. 5 and 8B to 8E, in the third process (S3), a first exposure process may be performed on the first area AR1 to form a first pattern PT1 and an alignment mark AMK. The first exposure process may be performed in a vacuum state.

A range in which the first exposure machine PRD1 performs the exposure process through one operation is indicated by a first exposure area LTA1. An area on which the first pattern PT1 is formed by the first exposure area LTA1 may correspond to the first area AR1. For example, the first exposure area LTA1 may be an area to which light is provided by the first exposure machine PRD1, and the first area AR1 may be an area on which the first pattern PT1 is substantially formed by passing through the exposure mask PMA1. Thus, the first area AR1 may be defined as having the same size as the first exposure area LTA1 or a size less than that the first exposure area LTA1. The first exposure area LTA1 may have a size equal to or less than that of the first exposure machine PRD1 in the plan view. For example, a length of the available first exposure area LTA1 of the first exposure machine PRD may be equal to or less than that of the first area AR1 in the first direction in a longitudinal direction (e.g., the first direction DR1).

The first exposure machine PRD1 may form a first pattern PT1 on the top surface UF and the bottom surface BF of the first area AR1. The first exposure machine PRD1 may include a first sub exposure machine SPD1 and a second sub exposure machine SPD2. The first exposure machine SPD1 may perform a first exposure process on the top surface UF of the first area AR1. The first exposure machine SPD1 may dispose a first exposure mask PMA1 on the top surface UF of the first area AR1.

A plurality of exposure lines PL may be defined on the first exposure mask PMA1. The exposure lines PL may be spaced apart from each other in the second direction DR2, and each of the exposure lines PL may extend in the first direction DR1. Although four exposure lines PL are defined on the first exposure mask PMA1 in the embodiment illustrated in FIG. 8C, this is only for convenience of description, and a greater number of exposure lines PL may be defined on the first exposure mask PMA1.

One exposure line PL may correspond to the first area AR1 including the first portion PP1 and the third part PP2 of the mask MK illustrated in, for example, FIG. 2. For example, the exposure line PL may include four groups GU and a plurality of exposure alignment holes (or exposure alignment openings) PRA. One group GU may correspond to one first cell area CEL1 illustrated in, for example, FIG. 2.

Each of the groups GU may include a plurality of first exposure holes (or first exposure openings) PRH1. The first exposure hole PRH1 may have the same shape as the first hole H1 illustrated in, for example, FIG. 2. For example, when viewed in the plan view, the first exposure hole PRH1 may have a rectangular shape. Portions overlapping the first exposure holes PRH1 on the top surface UF of the first area AR1 may be exposed to the outside of the first exposure mask PMA1.

The exposure alignment holes PRA may have an arrangement in which three holes arranged along the first direction DR1 are spaced apart from each other in the second direction DR2. The exposure alignment holes PRA may correspond to the alignment marks AM1 and AM2 of the mask MK illustrated in, for example, FIG. 2. In the illustrated embodiment, the exposure alignment holes PRA are defined for each area partitioned by the exposure lines PL. However, this is merely an example, and the exposure alignment holes PRA may be defined in only some of the areas partitioned by the exposure lines PL.

Each of the exposure alignment holes PRA may be a transmissive hole for forming a through-hole or may be a semi-transmissive hole for forming a recess part. The arrangement and/or number of the exposure alignment holes PRA may be variously changed. Also, a shape of each of the exposure alignment holes PRA may be the same as or different from that of each of the first exposure holes PRH1.

For example, referring to FIGS. 9A to 9C, the exposure alignment holes PRA, PRA-1, and PRA-2 may be provided in various shapes. For example, as illustrated in FIG. 9A, the exposure alignment holes PRA may be provided as a plurality of circles arranged in one direction. Each of the exposure alignment holes PRA may have a circular shape on the plane. Thus, the alignment marks AMPT1 and AMPT2 may be formed as a plurality of circular marks corresponding to the exposure alignment holes PRA.

Alternatively, as illustrated in FIG. 9B, the exposure alignment holes PRA-1 may be provided in a plurality of cross shapes arranged in one direction. Each of the exposure alignment holes PRA-1 may have a cross shape in the plane view. The cross shape may have a shape in which a bar portion B1 extending in the first direction DR1 and a bar portion B2 extending in the second direction DR2 cross (or intersect) each other. The bar portions B1 may be aligned in the first direction DR1. Thus, the alignment marks AMPT1 and AMPT2 may be formed as a plurality of cross-shaped marks corresponding to the exposure alignment holes PRA-1.

Alternatively, as illustrated in FIG. 9C, the exposure alignment hole PRA-2 may be provided in the shape of an integral bar extending in one direction. The exposure alignment hole PRA-2 may have a bar shape extending in the first direction DR1 on the plane. Thus, each of the alignment marks AMPT1 and AMPT2 may be formed as a single bar-shaped mark corresponding to the exposure alignment holes PRA-2.

Referring to FIGS. 8D and 8E, the first exposure machine SPD1 may irradiate light to the top surface UF of the first area AR1. Thus, the first pattern PT1 may be formed on the top surface UF of the first area AR1. For example, the first pattern PT1 may include a plurality of first hole patterns HPT1 corresponding to the shapes of the first exposure holes PRH1 of the first exposure mask PMA1. Chemical properties of portions of the first photoresist PR1, which are exposed to light through the first exposure holes PRH1, may be changed. In FIG. 8E, portions of the photoresist PR1 having the changed chemical properties are hatched for easy explanation. Also, a mask area MAT corresponding to any one of the exposure lines PL illustrated in, for example, FIG. 8C and corresponding to one mask MK (see, e.g., FIG. 2) is illustrated. For example, as illustrated in FIG. 8E, one mask sheet MS may be divided into four masks in the second direction DR2. However, this is merely an example, and only one mask may be formed in the second direction DR2 on one mask sheet MS or the mask sheet MS may be divided into a different number of masks through a design change.

The second exposure machine SPD2 may perform the first exposure process on the bottom surface BF of the first area AR1. The second exposure machine SPD2 may dispose a second exposure mask PMA2 on the bottom surface BF of the first area AR1. A plurality of second exposure holes PRH2 may be defined in the second exposure mask PMA2. The second exposure mask PMA2 may have the same shape as the first exposure mask PMA1. For example, each of the second exposure holes PRH2 may have the same shape as the first exposure holes PRH1, and the second exposure holes PRH2 may have the same structure as the first exposure holes PRH1. Portions overlapping the second exposure holes PRH2 on the bottom surface BF of the first area AR1 may be exposed to the outside of the second exposure mask PMA2. However, the shape of the second exposure mask PMA2 is not limited thereto. For example, each of the first exposure hole PRH2 of the second exposure mask PMA2 may have a shape different from that of the first exposure hole PRH1.

The second exposure machine SPD2 may irradiate light to the bottom surface BF of the first area AR1. A first pattern PT1 may be formed on the bottom surface BF of the first area AR1. The first pattern PT1 may correspond to the shape of the second exposure holes PRH2 of the second exposure mask PMA2. Chemical properties of portions exposed to the light through the second exposure holes PRH2 in the second photoresist PR2 of the mask sheet MS may be changed. Here, the exposure may also occur through the exposure alignment holes PRA. Portions of the first area AR1 of the mask sheet MS overlapping the exposure alignment holes PRA may be exposed to the light. Thus, the chemical properties of the portions exposed to light by the exposure alignment holes PRA in the first photoresist PR1 and the second photoresist PR2 of the mask sheet MS may be changed. The alignment patterns AMPT1 and AMPT2 may be patterns in which the chemical properties of the photoresists PR1 and PR2 are changed. According to an embodiment of the present disclosure, when the chemical properties of the portions exposed by the exposure holes PRH1 and PRH2 and the exposure alignment holes PRA are changed, the first exposure process for the first area AR1 may be ended (e.g., may be completed).

The exposure alignment holes PRA may be defined only in the first exposure mask PMA1, and exposure holes may not be defined in the second exposure mask PMA2. The alignment of the second area AR2, which will be described later, may be performed based on the top surface UF. Thereafter, even though the first pattern PT1 is formed as the holes through a developing process and an etching process, the alignment marks AMPT1 and AMPT2 may not be formed on a rear surface BF, and thus, the portions corresponding to the alignment marks AMPT1 and AMPT2 may not be sufficiently exposed. Thus, holes corresponding to the alignment marks AMPT1 and AMPT2 may not be formed. Alternatively, a portion corresponding to each of the alignment marks AMPT1 and AMPT2 may be formed as a recess part in which only a portion of the top surface UF is removed. Alternatively, a portion corresponding to each of the alignment marks AMPT1 and AMPT2 may remain in the final mask MK to remain as a photoresist pattern.

In some embodiments, for example, the exposure alignment holes PRA may also be formed in the second exposure mask PMA2. Thus, because the alignment is performed with respect to both the top surface UF and the bottom surface BF, a degree of the alignment of the mask sheet MS may be improved. Because each of the alignment marks AMPT1 and AMPT2 is full-tone or half-tone, portions corresponding to the alignment marks AMPT1 and AMPT2 may be formed as holes or recess parts through a subsequent developing process and an etching process.

A process of forming the mask MK will be described with reference to FIGS. 8F to 8H. FIGS. 8F to 8H are views describing a fourth process (S4), a fifth process (S5), and a sixth process (S6) as illustrated in FIG. 5. Referring to FIGS. 5, 8F, 8G, and 8H, in the fourth process (S4), the second area AR2 is disposed on the first exposure machine PRD1 of the exposure module PRM.

The first roller RO1 and the second roller RO2 may rotate. The first area AR1 on which the first pattern PT1 is formed may be carried out (or moved) to the outside of the first exposure machine PRD1. In this embodiment, a partial area of the first area AR1 overlaps the second area AR2 to define an overlapping area AR0. As a result, when the second area AR2 is disposed on the first exposure machine PRD1, a partial area of the first area AR1 corresponding to the third area AR3 may be disposed on the first exposure machine PRD1, and another partial area of the first area AR1 may be disposed between the first exposure machine PRD1 and the second roller RO2 or near the second roller RO2. A portion of the first area AR1 corresponding to the third area AR3 may be additionally exposed to the first exposure machine PRD1 during the exposure process of the second area AR2.

Referring to FIGS. 8G and 8H, in the fifth process S5, the second area AR2 and the second exposure area LTA2 may be aligned, and in the sixth process S6, the second pattern PT2 may be formed on a mask sheet MS. Each of the second pattern PT2 includes a plurality of second hole patterns HPT2 corresponding to the second holes H2 (see, e.g., FIG. 2). In FIG. 8H, portions of the photoresist PR1 having the changed chemical properties are hatched for easy explanation. Here, the alignment marks AMPT1 and AMPT2 may be used to align the second exposure area LTA2 and the second area AR2. The second exposure area LTA2 may be an area to which light for patterning is provided and may be an area exposed at a timing different from that of the first exposure area LTA1. The second exposure area LTA2 may have a size equal to or less than that of the first exposure machine PRD1 in the plan view. An alignment point PNT may be a camera or a pointer installed in the first exposure machine PRD1 or may be an alignment mark defined on the exposure mask. Because the alignment marks AMPT1 and AMPT2 are formed by changing the chemical properties by the exposure from an initial photoresist, the alignment marks AMPT1 and AMPT2 may be easily recognized by a special camera.

In FIG. 8F, the alignment point PNT is schematically indicated on the first exposure machine PRD1. According to this embodiment, a process of checking (or determining) whether or not the alignment point PNT and the alignment marks AMPT1 and AMPT2 match each other and/or a process of correcting the position of the mask sheet MS on the plane according to a degree of misalignment may be further performed. Thus, alignment accuracy between the exposure area of the first exposure machine PRD1 and the second area AR2 may be improved.

In some embodiments, an actual alignment operation between the exposure area and the second area AR2 may be performed based on whether the exposure mask for forming the second pattern PT2 and the alignment marks AMPT1 and AMPT2 are aligned. Referring to FIG. 8H, exposure alignment holes may be additionally defined at positions corresponding to the alignment marks AMTP1 and AMPT2 in addition to the exposure holes for the second pattern PT2 in the exposure mask used by forming the second pattern PT2 on the second area AR2. The exposure mask for forming the second pattern PT2 may be aligned at position matching the second area AR2 by checking (or determining) the alignment through a degree of the overlapping between the exposure alignment holes and the alignment marks AMPT1 and AMPT2 and performing the correction operation. In the state in which the second pattern PT2 is formed, the alignment marks AMTP1 and AMPT2 may be subjected to two exposure processes including a first exposure and a second exposure. However, this is merely an example, and when the exposure alignment holes are omitted in the exposure mask used in the secondary exposure, the alignment marks AMTP1 and AMPT2 may only undergo the first exposure process.

Referring to the alignment process in detail with reference to FIG. 8G, the second exposure area LTA2 and the second area AR2 may be aligned through the degree of misalignment between the first and second points PNT1 and PNT2 constituting the alignment point PNT of the second exposure area LTA2 and the first area AR1 and the first and second alignment marks AMPT1 and AMPT2. The second point PNT2 may be aligned with an intermediate mark of the second alignment marks AM1, and the degree of the misalignment between the first point PNT1 and the intermediate mark of the first alignment marks AM2 may be quantified as X-displacement dX and Y-displacement dY to determine the degree of the alignment.

When the X-displacement dX and the Y-displacement dY have values greater than or equal to a certain range (e.g., a predetermined range), the positions are determined to be misaligned, and thus, the position of the mask sheet MS or the exposure machine PRD1 may be changed to align the second area AR2 and the exposure area LTA2. When the X-displacement dX and the Y-displacement dY have values within the certain range, it is determined that the positions are aligned within an error range (e.g., are not misaligned), and then, the second exposure process may be performed.

The X-displacement dX may be a degree of misalignment in the X direction, that is, in the longitudinal direction of the mask sheet MS. The X-displacement dX may be identified from the degree of the misalignment in the left-right direction between the second point PNT2 and the second alignment mark AMPT2. The X-displacement dX may be determined as an alignment within an error range, for example, when the X-displacement is within about ±2.5 μm. For example, when the X-displacement dX is within about ±1.5 μm, it may be determined that the alignment is within the error range.

The Y-displacement dY may be a degree of misalignment in the Y direction, that is, the width direction of the mask sheet MS. In this embodiment, the Y-displacement dY may be identified from the degree of misalignment in a vertical direction between the second point PNT2 and the second alignment mark AMPT2. The Y-displacement dY may be determined as alignment within an error range, for example, when the X-displacement is within about ±2.0 μm. For example, when the Y-displacement dY is within about ±1.0 μm, it may be determined that the alignment is within the error range.

According to an embodiment of the present disclosure, the alignment between the mask sheet MS and the exposure machine PRD1 may be determined through the X-displacement dX and the Y-displacement dY, and thus, the alignment process may be performed based on the determined degree of the alignment. Thus, the second exposure process performed at a timing different from that of the first exposure process may be stably performed on the second area AR2. In this embodiment, although the X-displacement dX and the Y-displacement dY are obtained through a position difference between the intermediate marks of the alignment marks AM1 and AM2 and the points PNT1 and PNT2, the present disclosure is not limited thereto. For example, the X-displacement dX and the Y-displacement dY may be obtained through a position difference between the first alignment marks of the alignment marks AMPT1 and AMPT2 and the points PNT1 and PNT2. In some embodiments, for example, each of the points PNT1 and PNT2 may be provided to a size overlapping two or more alignment marks. The first point PNT1 may be provided in the shape of one oval or bar overlapping all of the first alignment marks AMPT1 and the second point PNT2 may be provided in the shape of one oval or bar overlapping all of the second alignment marks AMPT2. The alignment process between the second area AR2 and the second exposure area LTA2 according to an embodiment of the present disclosure may be performed in various suitable manners using the alignment marks AMPT1 and AMPT2.

Marks other than the alignment marks AMPT1 and AMPT2 may be disposed on the mask sheet MS. Such other marks may be used for correcting the alignment errors or monitoring the progress of the mask sheet. For example, other marks used in the alignment process, in addition to the alignment marks AMPT1 and AMPT2, may be disposed on the mask sheet MS. The corresponding mark(s) may be formed through a process different from that of the alignment marks AMPT1 and AMPT2. For example, the corresponding mark may be provided in a state in which it is already formed (e.g., may be previously formed) on the mask sheet MS or may be provided in a state formed in another process through a device other than the exposure machine PRD1.

In the illustrated embodiment, the second pattern PT2 is described as being formed through the first exposure machine PRD1 that forms the first pattern PT1. However, this is merely an example, and the second pattern PT2 may be formed through a separate exposure machine independently provided from (e.g., different from) the first exposure machine PRD1. In addition, after the first pattern PT1 is formed, the mask sheet MS may be wound and then unwound to form the second pattern PT2, or after forming the first pattern PT1 without a separate winding process, the process of forming the second pattern PT2 after aligning the second area AR2 at another place may be performed.

Thereafter, the mask sheet MS may be formed as the mask MK (see, e.g., FIG. 2) having the plurality of holes H1 and H2 (see, e.g., FIG. 2), which are respectively correspond to the first pattern PT1 and the second pattern PT2, through the developing process and the etching process. Here, as described above, patterns corresponding to the alignment marks AMPT1 and AMPT2 may or may not be formed on the mask MK depending on the degree of exposure to the alignment marks AMPT1 and AMPT2 or whether the etching process is performed. The process of manufacturing the mask according to an embodiment of the present disclosure may include various processes as long as the process includes the process of forming the alignment marks AMPT1 and AMPT2 and the alignment process using the same.

Referring to FIG. 8I, in the mask sheet MS1, the alignment marks AMPT1 and AMPT2 may be formed outside the area on which the patterns PT1 and PT2 are formed. In the illustrated embodiment, the alignment marks AMPT1 and AMPT2 are shown as being formed outside the mask area MAT and are not formed in the area between the hole patterns HPT1 and HPT2. In such an embodiment, the alignment marks AMPT1 and AMPT2 appear only in the state of the mask sheet MS1, and also, the masks corresponding to the alignment marks AMPT1 and AMPT2 may be omitted in the state in which the photoresists PR1 and PR2 are removed to form the mask. According to an embodiment of the present disclosure, a surface area occupied by the alignment marks AMPT1 and AMPT2 may be reduced, and the area on which the hole patterns HPT1 and HPT2 are formed may not be invaded (or used), and thus, the surface area on which the patterns PT1 and PT2 are formed may be widely secured. The alignment marks AMPT1 and AMPT2 according to an embodiment of the present disclosure may be provided at various positions and are not limited.

The above-described processes (S1 to S6) relate to the method for manufacturing the mask MK illustrated in, for example, FIG. 2, but embodiments of the present disclosure are not limited thereto. The above-described processes (S1 to S6) may be changed within the scope of the present disclosure. For example, the exposure module PRM may form a pattern corresponding to the clamping part CP illustrated in, for example, FIG. 2 on the pattern area PTA. For example, the exposure mask of the first exposure machine PRD1 may further include a groove corresponding to the clamping part CP. In such an embodiment, the first exposure machine PRD1 may rotate about 180° with respect to the first directional axis D1 between the first exposure process and the second exposure process. Here, the first directional axis DR1 may be a direction perpendicular to the top surface UF of the mask sheet MS as described above. Thus, the clamping part CP having a symmetrical shape with respect to the overlapping area AR0 may be formed.

According to an embodiment of the present disclosure, because the first exposure process and the second exposure process are separately performed on one pattern area PTA, a mask MK having a length greater than that of the available exposure area of the first exposure machine PRD1 may be manufactured. Thus, production efficiency of the display device may be improved.

According to an embodiment of the present disclosure, because the pattern area PTA of the mask sheet MS is arranged in parallel to the direction of gravity D3 during the first and second exposure processes, wrinkles may not be generated on the pattern area PTA of the mask sheet MS.

Thus, according to an embodiment of the present disclosure, even when a single mask is formed through a plurality of exposure processes, the two patterns PT1 and PT2 may have continuity and uniformity by improving the alignment. Thus, a large-area mask may be easily formed, and a defect rate of the display device using the mask may be reduced.

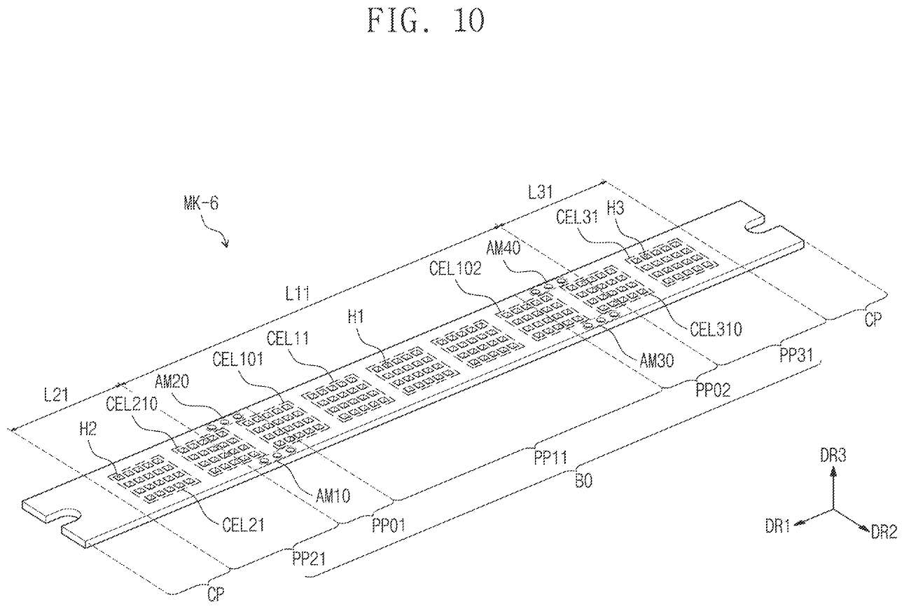

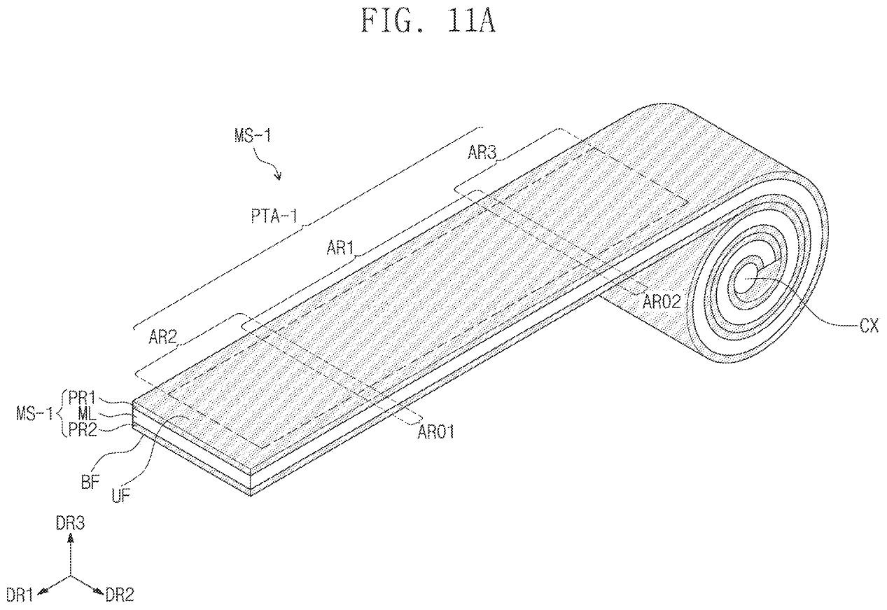

FIG. 10 is a perspective view of a mask according to an embodiment of the present disclosure. As illustrated in FIG. 10, in a mask MK-6, the body BO may have a first portion PP11, a second portion PP21, a third portion PP31, a first overlapping portion PP01, a second overlapping portion PP02, and a clamping part CP. The first overlapping portion PP01 may be disposed between the first portion PP11 and the second portion PP21. The second overlapping portion PP02 may be disposed between the second portion PP21 and the third portion PP31. The second portion PP2, the first overlapping portion PP01, the first portion PP11, the second overlapping portion PP02, and the third portion PP31 are sequentially arranged in the first direction DR1.

The sum of a length of the first portion PP11, a length of the first overlapping portion PP01, and a length of the second overlapping portion PP02 in the first direction DR1 may be a first length L11. The sum of a length of the second portion PP2 and a length of the overlapping portion PP01 in the first direction DR1 may be a second length L2. A sum of a length of the third portion PP31 and a length of the second overlapping portion PP02 in the first direction DR1 may be the third length L31.

First cell areas CEL11 may be defined in the first portion PP11, the first overlapping portion PP01, and the second overlapping portion PP02. A plurality of first holes (or first openings) H1 may be defined in each of the first cell areas CEL11. The first holes H1 are illustrated as corresponding to the first holes H1 illustrated in FIG. 2 but are not limited thereto.

Second cell areas CEL21 may be defined in the second portion PP21 and the first overlapping portion PP01. A plurality of second holes (or second openings) H2 may be defined in each of the second cell areas CEL21. The second holes H2 are illustrated as corresponding to the first holes H1 but are not limited thereto.

The third cell areas CEL31 may be defined on the third portion PP3 and the second overlapping portion PP02. The third cell areas CEL31 may include a third cell area CEL31 disposed only on the third portion PP31 and a third cell area CEL310 disposed over the third portion PP31 and the second overlapping portion PP02. A plurality of third holes (or third openings) H3 may be defined in each of the third cell areas CEL31. Although the third holes H3 are illustrated to correspond to the third holes H3, the present disclosure is not limited thereto.

A first cell area CEL101 adjacent to the second cell areas CEL21 from among the first cell areas CEL11 may be defined over the first portion PP1 and the first overlapping portion PP01, and a first cell area CEL102 adjacent to the third cell areas CEL31 from among the first cell areas CEL11 may be defined over the first portion PP1 and the second overlapping portion PP02. A second cell area CEL201 adjacent to the first cell areas CEL11 from among the second cell areas CEL21 may be defined over the second portion PP21 and the first overlapping portion PP0, and a third cell area CEL301 adjacent to the first cell areas CEL11 from among the third cell areas CEL3 may be defined over the third portion PP31 and the second overlapping portion PP02. As a result, a portion of the first cell area CEL101 and a portion of the second cell area CEL201 may be defined on the first overlapping portion PP01, and a portion of the other first cell area CEL102 and a portion of the third cell area CEL301 may be defined on the second overlapping portion PP02.

Each of the first cell areas CEL101 and CEL102 defined in the overlapping portion PP01 may partially include a hole (or opening) having a shape different from that of the first hole H1. A second cell area CEL210 defined in the overlapping portion PP01 may partially include a hole (or opening) having a shape different from that of the second hole H2. A third cell areas CEL310 defined in the overlapping portion PP02 may partially include a hole (or opening) having a shape different from that of the third hole H3.

A mask MK-6 according to an embodiment of the present disclosure may include a plurality of alignment marks AMPT10, AMPT20, AMPT30, and AMPT40. The alignment marks AMPT10, AMPT20, AMPT30, and AMPT40 may be defined on the overlapping portions PP01 and PP02. As described above, each of the alignment marks AMPT10, AMPT20, AMPT30, and AMPT40 may be defined as a hole or recess part.

The first alignment marks AMPT10 and the second alignment marks AMPT20 are disposed on the first overlapping portion PP01. The first alignment marks AMPT10 and the second alignment marks AMPT20 may be disposed to be spaced apart from each other in the second direction DR2. The first alignment marks AMPT10 and the second alignment marks AMPT20 may be aligned at positions parallel to and overlapping each other when viewed in the second direction DR2. Each of the first alignment marks AMPT10 and the second alignment marks AMPT20 is illustrated as three holes arranged in the first direction DR1, but the present disclosure is not limited thereto.

The third alignment marks AMPT30 and the fourth alignment marks AMPT40 are disposed on the second overlapping portion PP02. The third alignment marks AMPT30 and the fourth alignment marks AMPT40 may be disposed to be spaced apart from each other in the second direction DR2. The third alignment marks AM30 and the fourth alignment marks AMPT40 may be aligned at positions parallel to and overlapping each other when viewed in the second direction DR2. Each of the third alignment marks AMPT30 and the fourth alignment marks AMPT40 is illustrated as three holes arranged in the first direction DR1, but the present disclosure is not limited thereto.

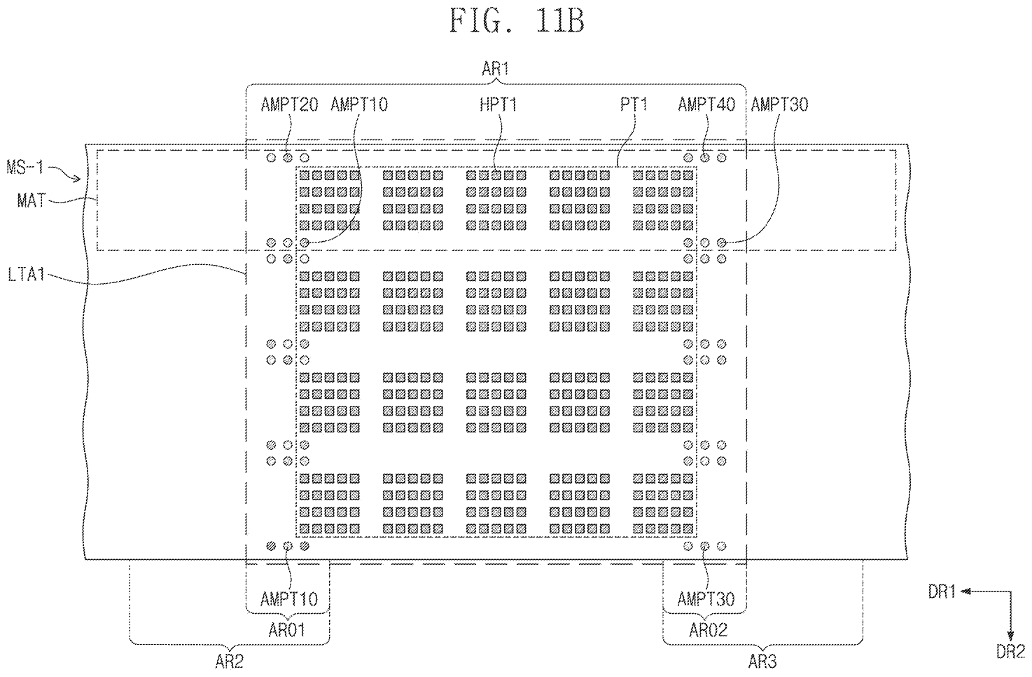

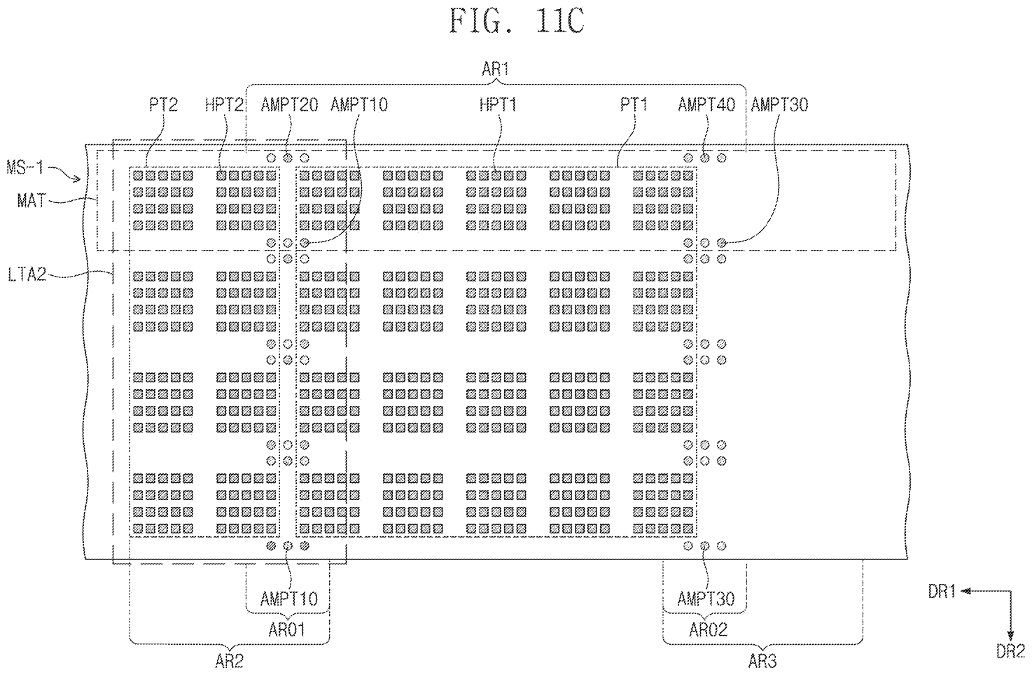

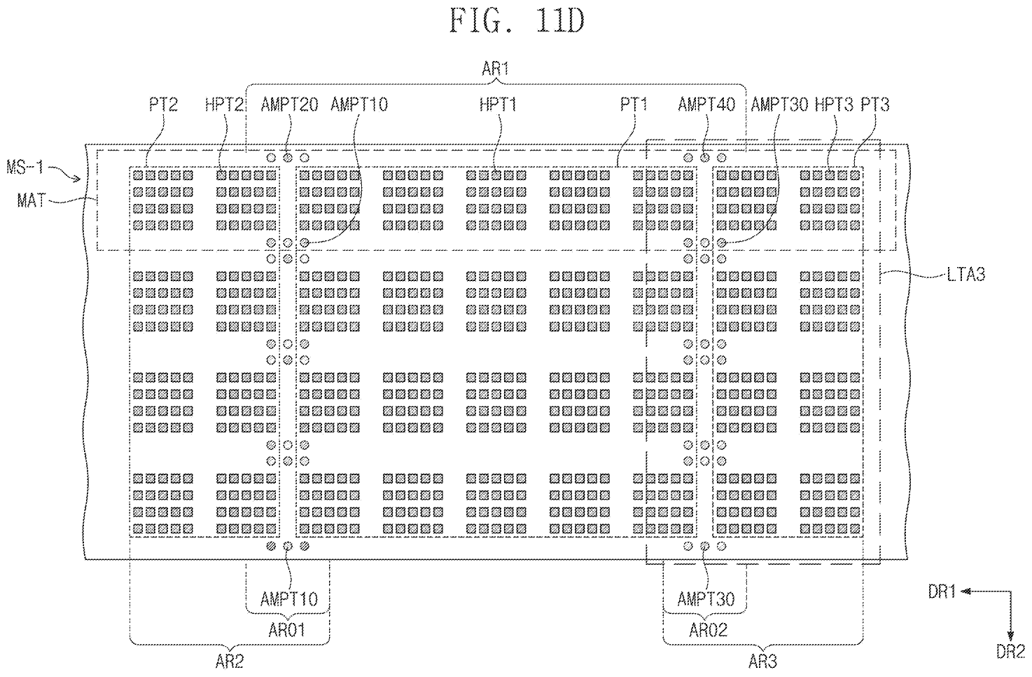

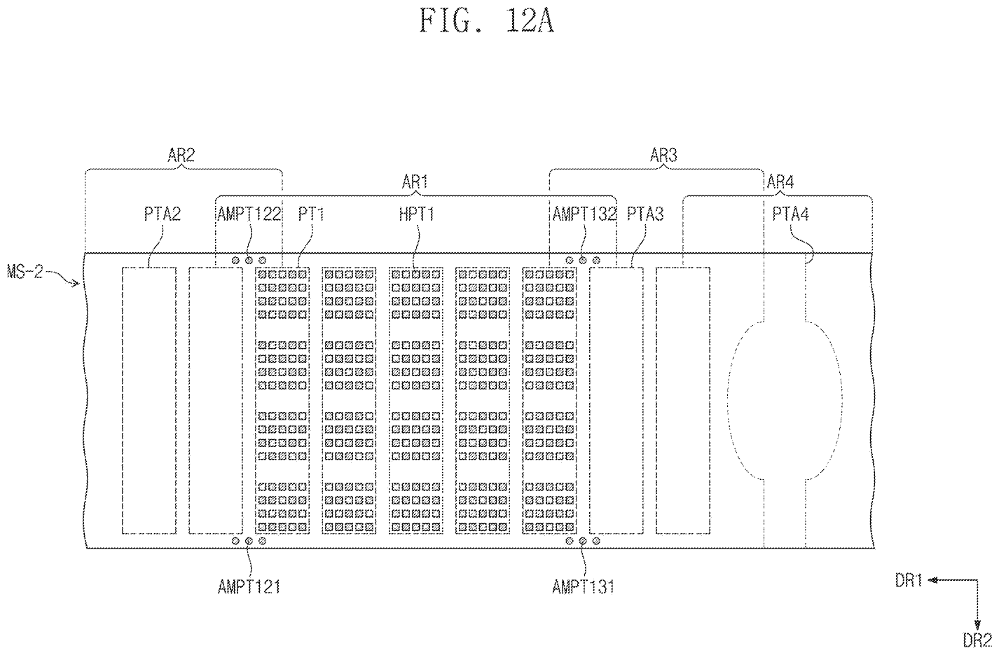

FIGS. 11A to 11D are views describing a process of manufacturing a mask illustrated in FIG. 10. FIG. 11 is a view of an example of a shape of the mask sheet illustrated in FIG. 10. FIG. 11A is illustrated to correspond to FIG. 7. Hereinafter, duplicated descriptions may be omitted.

Referring to FIG. 11A, a plurality of pattern areas PTA-1 may be defined on a mask sheet MS-1, and each of pattern areas PTA-1 may have a first area AR1, a second area AR2, a third area AR3, a first overlapping area AR01, and a second overlapping area AR02. The first overlapping area AR01 may be an area at where the first area AR1 and the second area AR2 overlap each other, and the second overlapping area AR02 may be an area at where the second area AR2 and the third area AR3 overlap each other.

FIGS. 11B to 11D are views describing processes of sequentially forming the first to third patterns PT1, PT2, and PT3. Referring to FIG. 11B, the first pattern PT1 is formed on the first area AR1. In some embodiments, the first exposure area LTA1 is provided by the first exposure machine PRD1 (see, e.g., FIG. 8A), and the first pattern PT1 is formed through one exposure. The first pattern PT1 includes a plurality of first hole patterns HPT1.

In this embodiment, a length of the first area AR1 and a length of the second area AR2 in the first direction DR1 may be different from each other. Also, the length of the first area AR1 and the length of the third area AR3 in the first direction DR1 may be different from each other. However, this is merely an example, and the first area AR1 may be defined to have the same length as the second area AR2 or the third area AR3 in the first direction DR1.

The alignment marks AM10, AM20, AM30, and AM40 may be formed on the first area AR1. The alignment marks AM10, AM20, AM30, and AM40 are formed together with the first pattern PT1 on the first exposure area LTA1. For example, the first pattern PT1 and the alignment marks AMPT10, AMPT20, AMPT30, and AMPT40 may be concurrently (or simultaneously) formed via one photomask.

Thereafter, referring to FIG. 11C, the second area AR2 may be disposed on the exposure machine PRD1, and the second pattern PT2 may be formed. The second pattern PT2 includes a plurality of second hole patterns HPT2. A position of the mask sheet MS-1 may be aligned so that the second area AR2 and the second exposure area LTA2 match each other. Checking (or determining) whether or not the mask sheet MS-1 is aligned and correcting any (substantial) misalignment may be performed by using the alignment marks AM10 and AM20. The second exposure area LTA2 and the second area AR2 may match each other through the exposure alignment hole formed in the photomask or a pointer installed in the exposure machine, and thus, the position of the mask sheet MS-1 may be easily aligned.

The alignment of the second area AR2 means that the second area AR2 and the first area AR1 overlap each other when viewed in at least the first direction DR1. Also, because the alignment marks AM10 and AM20 formed in the first area AR1 are used, a portion of the second area AR2 may overlap the first area AR1. In this embodiment, the second exposure area LTA2 may have a size different from that of the first exposure area LTA1. For example, even if the same exposure machine is used, the exposure range may be designed in various manners.

Thereafter, referring to FIG. 11D, the third area AR3 may be disposed on the exposure machine PRD1, and the third pattern PT3 may be formed. The third pattern PT3 includes a plurality of third hole patterns HPT3, each of which has a shape corresponding to each of the third holes HH3. Here, the positions of the mask sheet MS-1 may be aligned so that the third area AR3 and the third exposure area LTA3 match each other. Checking (or determining) whether or not the mask sheet MS-1 is aligned and correcting any (substantial) misalignment may be performed by using the alignment marks AM30 and AM40. The third exposure area LTA3 and the third area AR3 may match each other through the exposure alignment hole formed in the photomask or a pointer installed in the exposure machine, and thus, the position of the mask sheet MS-1 may be easily aligned.

The alignment of the third area AR3 means that the third area AR3 and the first area AR1 overlap each other when viewed in at least the first direction DR1. Also, because the alignment marks AMPT30 and AMPT40 formed in the first area AR1 are used, a portion of the third area AR3 may overlap the first area AR1. In this embodiment, the third exposure area LTA3 may have a size different from that of the first exposure area LTA1. For example, the mask sheet MS-1 may be exposed through a plurality of exposure machines, and even if the same exposure machine is used, the exposure range may be variously designed.

According to an embodiment of the present disclosure, the first area AR1 may correspond to a central area of the mask, and the second area AR2 and the third area AR3 may correspond to outer areas of the mask relative to the first area AR1. A surface area of the first area AR1 may be larger than that of the second area AR2 or the third area AR3. For example, one exposure process may be performed on the widest area based on the central area of the mask, and then, patterns may be formed on an area close to the outer area of the mask through the exposure process. Thus, whether or not the outer area is aligned with respect to the center area of the mask may be determined, and thus, the alignment may be facilitated and a degree of the alignment may be improved.

According to an embodiment of the present disclosure, one mask may be formed through multiple exposure processes (e.g., two or more times). Here, the areas AR1, AR2, AR3 of the mask sheet MS-1 may be aligned in the first direction DR1 through the alignment marks AMPT10, AMPT20, AMPT30, and AMPT40, and thus, the patterns having continuity in the first direction may be easily formed. Thus, even when the length of the mask in the first direction DR1 increases, the mask may be stably generated (or formed), and a process defect rate of the display device may be reduced.

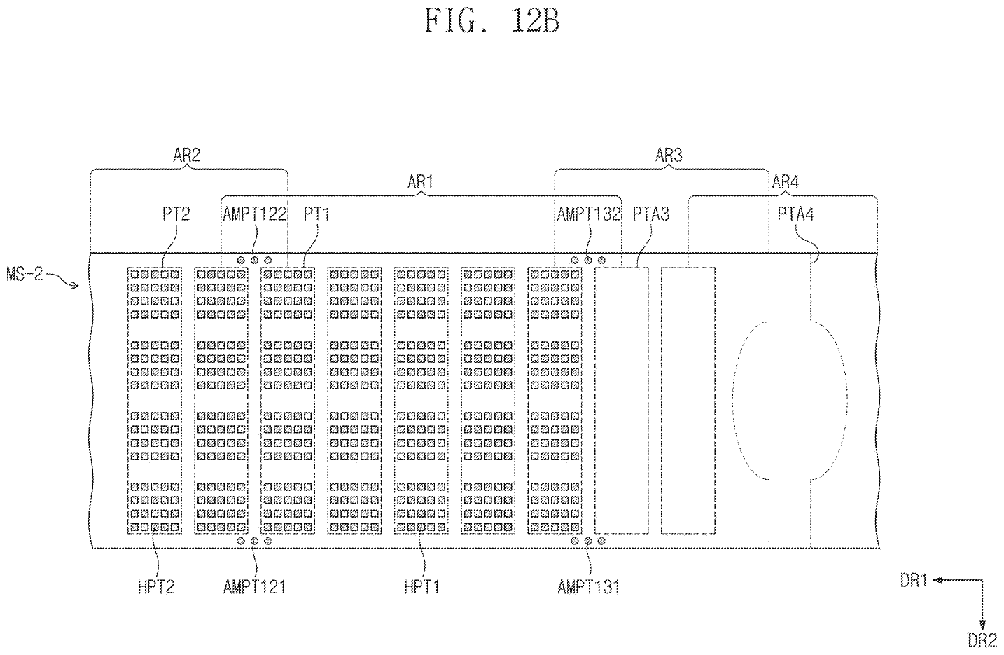

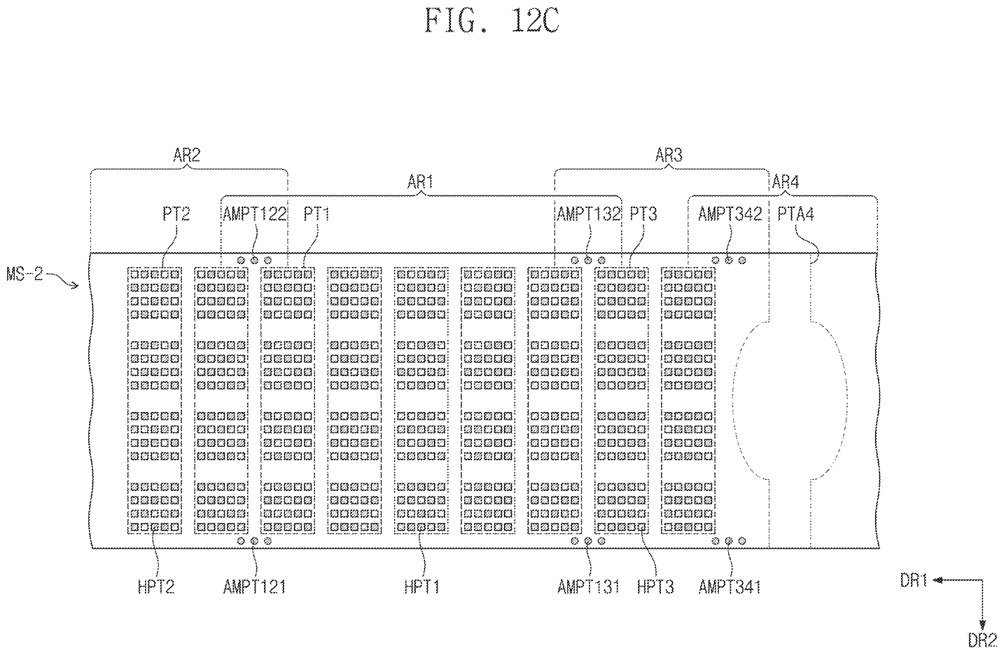

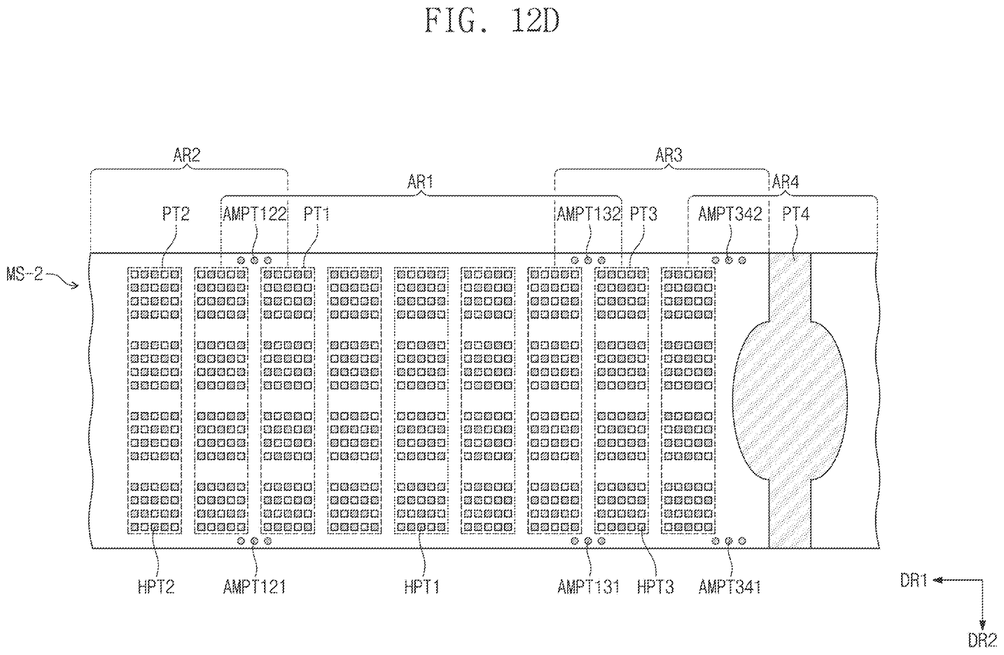

FIGS. 12A to 12D views describing a process of manufacturing the mask illustrated in FIG. 10. FIGS. 12A to 12D illustrate a manufacturing process different from that of FIGS. 11A to 11D. Hereinafter, duplicated descriptions may be omitted.

Referring to FIGS. 12A to 12D, first to fourth areas AR1, AR2, AR3, and AR4 may be defined on a mask sheet MS-2. Each of the first to fourth areas AR1, AR2, AR3, and AR4 may be an area that undergoes exposure processes performed at different timings and may correspond to exposure areas provided at different timings.

Referring to FIG. 12A, a first pattern PT1 is formed on the first area AR1 of the mask sheet MS-2 through a first exposure process. Here, alignment marks AMPT121, AMPT122, AMPT131, and AMPT132 may also be formed. The alignment marks AMPT121, AMPT122, AMPT131, and AMPT132 are formed on an area on which the first area AR1 and the second area AR2 overlap each other and an area on which the first area AR1 and the third area AR3 overlap each other.

Thereafter, referring to FIG. 12B, a second pattern PT2 is formed on the second area AR2. Here, alignment of the second area AR2 and the first area AR1 with respect to the first direction DR1 may be performed by using the alignment marks AMPT121 and AMPT122. Thus, the second pattern PT2 may be stably formed on the expected pattern area PTA2 designed to be aligned with the first pattern PT1.

Thereafter, referring to FIG. 12C, a third pattern PT3 is formed on the third area AR3. Here, alignment of the third area AR3 and the first area AR1 in the first direction DR1 may be performed by using the alignment marks AMPT131 and AMPT132. Thus, the third pattern PT3 may be stably formed on the expected pattern area PTA3 designed to be aligned with the first pattern PT1.

Additional alignment marks AMPT341 and AMPT342 may be formed on the third area AR3. The additional alignment marks AMPT341 and AMPT342 may be concurrently (or simultaneously) formed when the third pattern PT3 is formed. For example, the additional alignment marks AMPT341 and AMPT342 and the third pattern PT3 may be concurrently (or simultaneously) formed through one photomask.

Thereafter, referring to FIG. 12D, a fourth pattern PT4 may be formed on the fourth area AR4. The fourth pattern PT4 is formed at a position spaced apart from the third pattern PT3. The fourth pattern PT4 may be a pattern for forming the clamping part CP (see, e.g., FIG. 2).

The fourth area AR4 may be aligned through the additional alignment marks AMPT341 and AMPT342. For example, the third area AR3 and the fourth area AR4 may be aligned with respect to the first direction DR1 by using the alignment marks AMPT341 and AMPT342. Thus, the fourth pattern PT4 may be stably formed on the expected pattern area PTA4 designed to be aligned with the third pattern PT3.

According to an embodiment of the present disclosure, the exposure process for forming the clamping part may be performed separately from the process of forming the patterns PT1, PT2, and PT3. Also, a process of aligning the area for forming the clamping part may be further performed. Here, the additional alignment marks AMPT341 and AMPT342 formed when the third pattern PT3 is formed may be used. Thus, a mask having improved alignment may be provided.

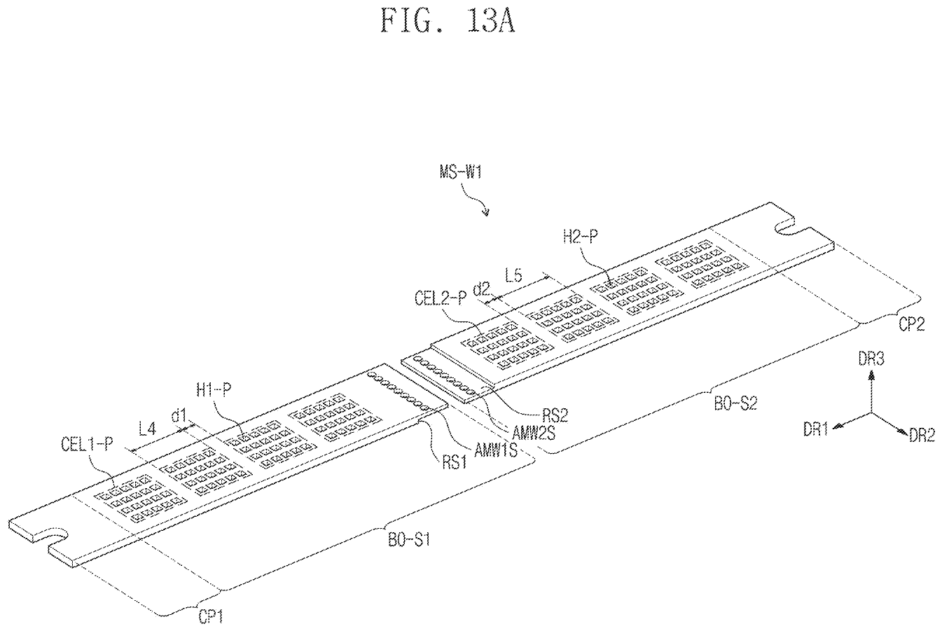

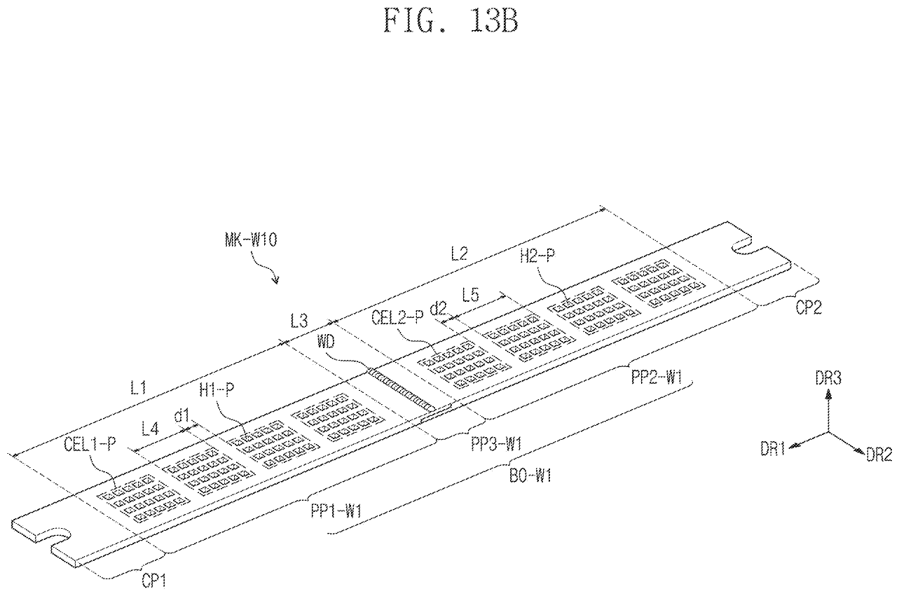

FIGS. 13A and 13B are views describing a mask according to an embodiment of the present disclosure. FIG. 13A illustrates separated masks MK-W1, and FIG. 13B illustrates coupled mask MK-W10. Hereinafter, duplicated descriptions may be omitted.

Referring to FIGS. 13A and 13B, the mask MK-W10 may be formed by coupling separated sub masks MS-W1. For example, the sub masks MS-W1 include a first clamping part CP1, a first body BO-S1, a second clamping part CP2, and a second body BO-S2.

The first body BO-S1 has a length extending in the first direction DR1. The first clamping part CP1 extends from one side of the first body BO-S1 in a direction parallel to the first direction DR1 to form an integral shape with the first body BO-S1.

The first body BO-S1 may include a plurality of first cell areas CEL1-P. The first cell areas CEL1-P are spaced apart from each other in the first direction DR1. A plurality of first holes (or first openings) H1-P may be defined in each of the first cell areas CEL1-P. Each of the first holes H1-P passes through (or extends through) the first body BO-S1. The first cell areas CEL1-P and the first holes H1-P are illustrated to correspond to the first cell areas CEL1 and the first holes H1 illustrated in, for example, FIG. 2, and duplicated descriptions thereof may be omitted hereinafter.

The first body BO-S1 may further include a first recess part RS1 and a plurality of first alignment marks AMW1S. The first recess part RS1 may be defined in a rear surface of the first body BO-S1 and may be a recessed portion. Thus, the first recess part RS1 may have a thickness less than that of each of other areas of the first body BO-S1.

The first alignment marks AMW1S may be defined to overlap the first recess part RS1. Although the first alignment marks AMW1S are illustrated as a plurality of holes (or openings) arranged in the second direction DR2, the present disclosure is not limited thereto. Each of the first alignment marks AMW1S may be a through-hole or a recess part and may be designed to have various planar shapes.

The second body BO-S2 has a length extending in the first direction DR1. The first clamping part CP1 extends from one side of the second body BO-S2 in a direction parallel to the first direction DR1 to form an integral shape with the second body BO-S2.

The second body BO-S2 may include a plurality of first cell areas CEL2-P. The second cell areas CEL2-P are spaced apart from each other in the first direction DR1. A plurality of second holes (or second openings) H2-P may be defined in each of the second cell areas CEL2-P. Each of the second holes H2-P passes through (or extends through) the second body BO-S2. The second cell areas CEL2-P and the second holes H2-P are illustrated to correspond to the second cell areas CEL2 and the second holes H2 illustrated in, for example, FIG. 2, and duplicated descriptions thereof may be omitted hereinafter.

The second body BO-S2 may further include a second recess part RS2 and a plurality of second alignment marks AMW2S. The second recess part RS2 may be defined on a top surface of the second body BO-S2 and may be a recessed portion. Thus, the second recess part RS2 may be provided with a thickness less than that of each of other areas of the second body BO-S2.

The second alignment marks AMW2S may be defined to overlap the second recess part RS2. The second alignment marks AMW2S are illustrated to correspond to the first alignment marks AMW1S. Each of the second alignment marks AMW2S may be a through-hole or a recess part and may be designed to have various planar shapes.

Referring to FIG. 13B, the mask MK-W10 includes a body BO-W1 formed by coupling the first body BO-S1 and the second body BO-S2. The body BO-W1 may include a first portion PP1-W1, a second portion PP2-W1, and a third portion PP3-W1 disposed between the first portion PP1-W1 and the second portion PP2-W1. Here, the first body BO-S1 and the second body BO-S2 may have shapes engaged with each other in the first direction DR1. Thus, the first body BO-S1 may have a first recess part RS1, and the second body BO-S2 may have a second recess part RS2.

When the first body BO-S1 and the second body BO-S2 are coupled to each other, the first recess part RS1 and the second recess part RS2 may overlap each other in the plan view. For example, the first recess part RS1 is disposed on the second recess part RS2. Thus, a sum of a thickness of the first recess part RS1 and a thicknesses of the second recess part RS2 may be less than or equal to a thickness of each of the bodies BO-S1 and BO-S2.

According to an embodiment of the present disclosure, even when the sub masks MK-W1 are formed through different exposure processes, the first cell areas CEL1-P and the second cell areas CEL2 may be formed in a state of being aligned with each other through the alignment marks AMW1S and AMW2S.

Also, when the first recess part RS1 overlaps the second recess part RS2, the first recess part RS1 and the second recess part RS2 may be aligned with each other by the first alignment marks AMW1S and the second alignment marks AMW2S. According to an embodiment of the present disclosure, whether or not the first body BO-S1 and the second body BO-S2 are aligned with each other are determined through whether or not the first alignment marks AMW1S and the second alignment marks AMW2S match each other and, thus, may be disposed at an ideal (or overlapping) position via correction thereof. Thus, the alignment of the masks MK-W10 may be improved, and a defect rate may be reduced.

Also, according to an embodiment of the present disclosure, the mask MK-W10 may further include a welding part WD according to a welding process. The welding part WD may be formed along the first alignment marks AMW1S and the second alignment marks AMW2S or within the first alignment marks AMW1S and the second alignment marks AMW2S, and thus, surface uniformity may be improved and bonding force may increase to improve process reliability of the mask SK-W10.

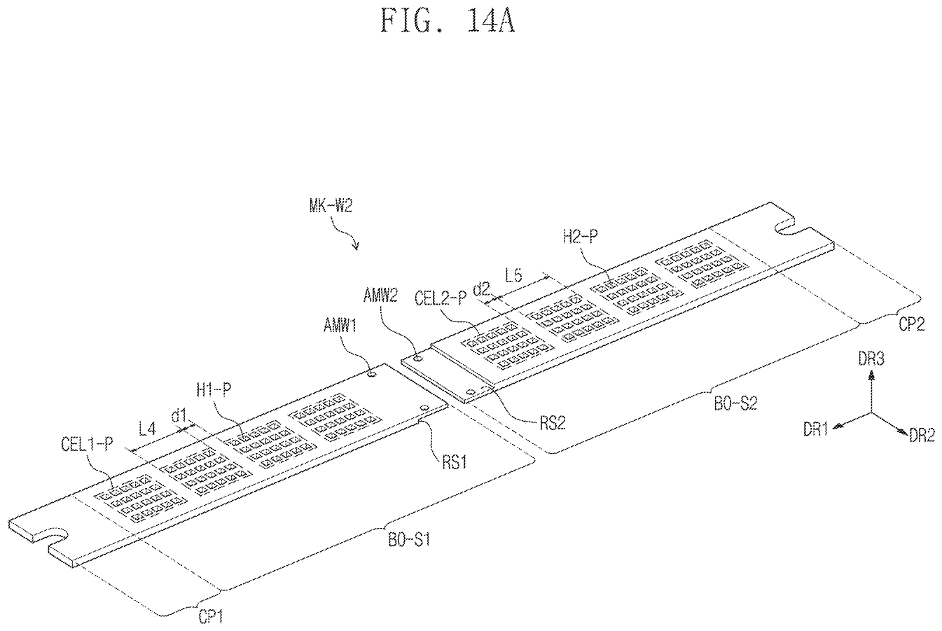

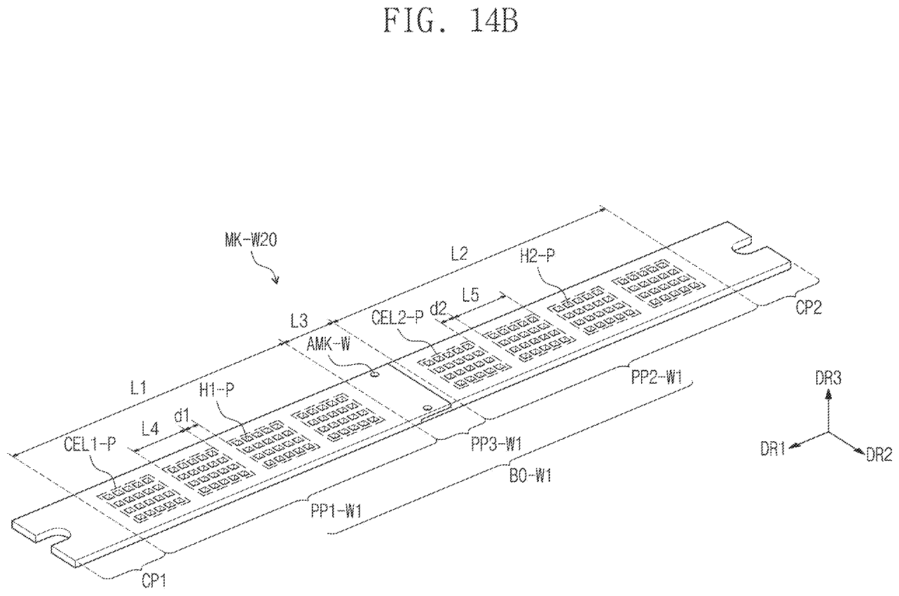

FIGS. 14A and 14B are views describing a mask according to an embodiment of the present disclosure. FIG. 14A illustrates separated masks MK-W2, and FIG. 14B illustrates coupled mask MK-W20. Hereinafter, duplicated descriptions may be omitted.

Referring to FIGS. 14A and 14B, the mask MK-W20 may be formed by coupling the separated sub masks MS-W2. The sub masks MS-W2 include a first clamping part CP1, a first body BO-S1, a second clamping part CP2, and a second body BO-S2. Duplicated description may be omitted.

In this embodiment, the first alignment marks AMW1 may be defined as two holes spaced apart from each other in the second direction DR2. Correspondingly, the second alignment marks AMW2 may be defined as two holes spaced apart from each other in the second direction DR2. The first alignment marks AMW1 and the second alignment marks AMW2 are aligned to form an alignment mark AMK-W of the mask MK-W20. According to an embodiment of the present disclosure, the number of alignment marks may be variously designed and is not limited.

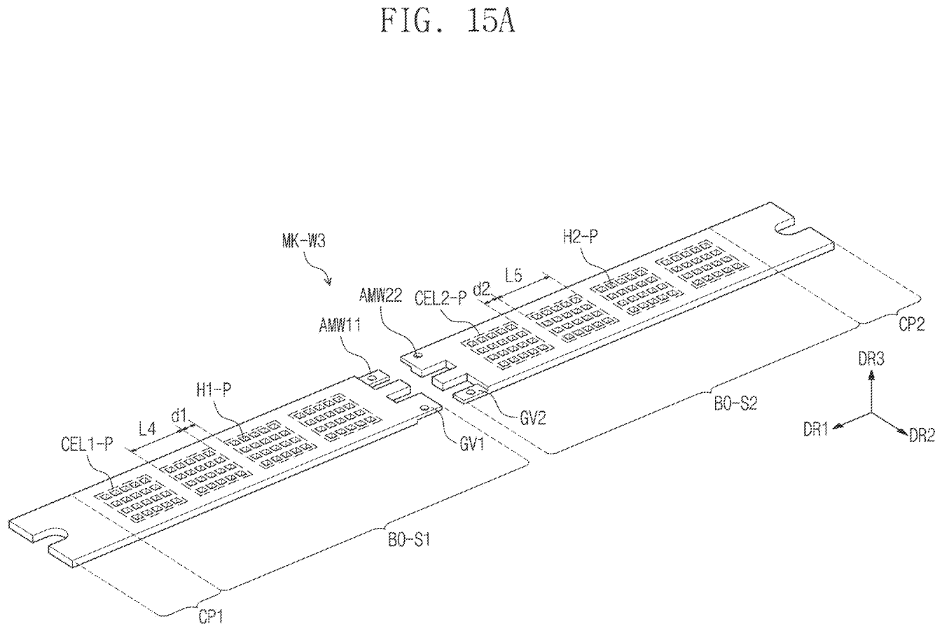

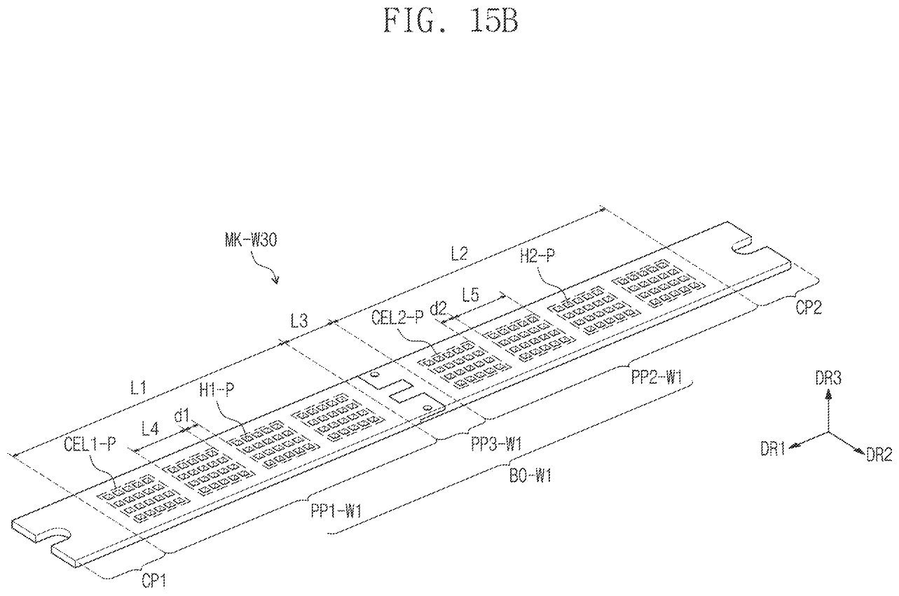

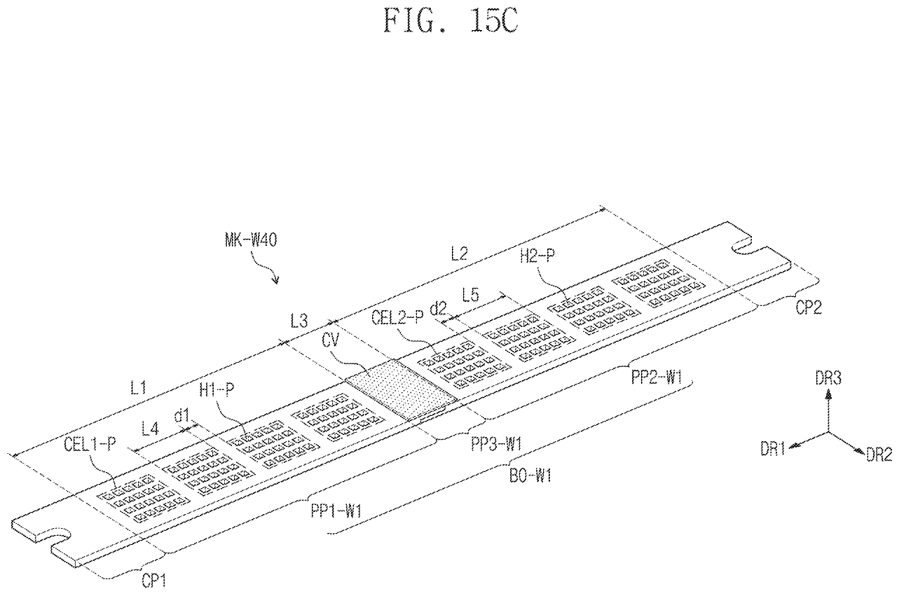

FIGS. 15A to 15C are views describing a mask according to an embodiment of the present disclosure. FIG. 15A illustrates separated masks MK-W3, and FIGS. 15B and 15C illustrate coupled masks MK-W30 and MK-40. Hereinafter, duplicated descriptions may be omitted.

Referring to FIGS. 15A and 15B, the mask MK-W30 may be formed by coupling the separated sub masks MS-W3. The sub masks MS-W3 include a first clamping part CP1, a first body BO-S1, a second clamping part CP2, and a second body BO-S2. Duplicated description may be omitted.

The first body BO-S1 and the second body BO-S2 may have a shape engaged with each other in the first direction DR1. For example, the first body BO-S1 may include a first groove GV1, and the second body BO-S2 may include a second groove GV2.

The first groove GV1 may be defined as a side surface of the first body BO-S1, such as a side coupled to the second body BO-S2, and may be (or may have) a plurality of curved portions.

The first alignment marks AMW11 may be defined to overlap the first groove GV1. Although the first alignment marks AMW11 are illustrated as two holes spaced apart in the second direction DR2, an embodiment of the present disclosure is not limited thereto. An area of the first grooves GV1 in which the first alignment marks AMW11 is defined may be provided to have a thickness less than that of each of other areas.

The second groove GV2 may be defined as a side surface of the first body BO-S2, such as a side coupled to the first body BO-S1, and may be (or may have) a plurality of curved portions.

The second alignment marks AMW22 may be defined to overlap the second groove GV2. The second alignment marks AMW22 are illustrated as two holes spaced apart in the second direction DR2 but is not limited thereto. An area of the second grooves GV2 in which the second alignment marks AMW22 is defined may be provided to have a thickness less than that of each of other areas.

The second body BO-S2 may include a plurality of second cell areas CEL2-P. The second cell areas CEL2-P are spaced apart from each other in the first direction DR1. A plurality of second holes (or second openings) H2-P may be defined in each of the second cell areas CEL2-P. Each of the second holes H2-P passes through (or extends through) the second body BO-S2. The second cell areas CEL2-P and the second holes H2-P are illustrated to correspond to the second cell areas CEL2) and the second holes H2 illustrated in, for example, FIG. 2, and duplicated descriptions thereof may be omitted hereinafter.

Referring to FIG. 15B, in the mask MK-W30, the first body BO-S1 and the second body BO-S2 are coupled to form one body BO-W1. In this case, the first groove GV1 and the second groove GV2 may overlap each other in the plan view. For example, the first groove GV1 and the second groove GV2 may be engaged and coupled to each other. That is, a portion protruding from the first groove GV1 may correspond to a concave portion from the second groove GV2.

According to an embodiment of the present disclosure, even when the sub masks MK-W3 are formed through different exposure processes, the first cell areas CEL1-P and the second cell areas CEL2 may be formed in a state of being aligned with each other through the alignment marks AMW11 and AMW22. Duplicated description may be omitted.

Also, when the first groove GV1 and the second groove GV2 overlap each other, the first groove GV1 and the second groove GV2 may be aligned by the first alignment marks AMW11 and the second alignment marks AMW22. According to an embodiment of the present disclosure whether or not the first body BO-S1 and the second body BO-S2 are aligned with each other is determined through whether or not the first alignment marks AMW11 and the second alignment marks AMW22 match each other and, thus, may be disposed at an ideal (e.g., overlapping) position through correction thereof. Thus, the alignment of the masks MK-W30 may be improved and a defect rate may be reduced.

Referring to FIG. 15C, the mask MK-40 may further include a cover CV. The cover CV may be a conductive layer and covers a portion to which the sub masks are coupled, that is, an overlapping portion PP3-W1. Thus, even when the overlapping portion PP3-W1 has an uneven surface by welding or the like, the uneven surface may be covered by the cover CV. In addition, because the cover CV covers a coupled boundary portion, damage of the mask MK-W40, such as separation of the mask MK-W40, may be prevented.

According to the present disclosure, the mask for the large-area deposition may be easily generated.

According to the present disclosure, the defect rate of the display device may be reduced.

It will be apparent to those skilled in the art that various modifications and deviations can be made in the present disclosure. Thus, it is intended that the present disclosure covers the modifications and deviations of and to the present disclosure provided they come within the scope of the appended claims and their equivalents. Accordingly, the technical scope of the present disclosure should not be limited to the contents described in the detailed description of the specification.

What is claimed is:

1. A mask comprising:
a body having a length in a first direction and comprising:
a plurality of first cell areas arranged in the first direction and respectively comprising a plurality of first holes; and
a plurality of second cell areas respectively comprising a plurality of second holes; and
a clamping part protruding from the body in the first direction and being integral with the body,
wherein an alignment mark is defined on the body and is offset from the first holes and the second holes, and
wherein the alignment mark overlaps the first and second cell areas when viewed in a second direction crossing the first direction.

2. The mask of claim 1, wherein the alignment mark is a hole or a recess.

3. The mask of claim 1, wherein the alignment mark comprises a photoresist.

4. The mask of claim 1, wherein the alignment mark comprises a plurality of marks arranged in the first direction.

5. The mask of claim 4, wherein the alignment mark comprises a first alignment mark and a second alignment mark spaced apart from each other in the second direction with the first holes and the second holes therebetween,
wherein each of the first and second alignment marks comprises the marks, and
wherein the marks of each of the first and second alignment marks are aligned with each other in the second direction.

6. The mask of claim 5, wherein each of the marks has a circular, oval, or cross shape on a plane.

7. The mask of claim 1, wherein the alignment mark comprises a first alignment mark and a second alignment mark spaced apart from each other in the second direction with the first holes and the second holes therebetween,
wherein each of the first and second alignment marks has a bar shape extending in the first direction, and
wherein the marks of each of the first and second alignment marks are aligned with each other in the second direction.

8. The mask of claim 7, wherein a length of each of the first and second alignment marks in the first direction is greater than a distance between adjacent cell areas of the first and second cell areas.

9. The mask of claim 1, wherein the body comprises:
a first body on which the first cell areas are defined; and
a second body on which the second cell areas are defined, and
wherein the alignment mark is provided in plurality, and the plurality of alignment marks are respectively defined on the first body and the second body to overlap each other on a plane.

10. The mask of claim 9, further comprising a welding part configured to couple the first body to the second body.

11. The mask of claim 10, wherein the welding part overlaps the alignment mark on the plane.

12. The mask of claim 9, wherein the first body and the second body are engaged with each other in the first direction.

13. The mask of claim 1, wherein the alignment mark is on an area on which the first cell areas and the second cell areas are adjacent to each other, and
wherein the number of first cell areas and the number of second cell areas are the same.

14. The mask of claim 1, wherein the alignment mark is on an area on which the first cell areas and the second cell areas are adjacent to each other, and
wherein the number of first cell areas and the number of second cell areas are different from each other.

15. The mask of claim 14, wherein the number of first cell areas is greater than that of second cell areas.

16. A method for manufacturing a mask, the method comprising:
arranging a mask sheet comprising a pattern area, on which a first area and a second area are defined, on a first roller and a second roller;
allowing the first roller and the second roller to rotate so that the pattern area is on an exposure module;
performing, through the exposure module, a first exposure process on the first area to form a first pattern and an alignment mark on the first area;
aligning the exposure module with the second area through the alignment mark; and
performing, through the exposure module, a second exposure process on the second area to form a second pattern on the second area.

17. The method of claim 16, wherein the first area and the second area partially overlap each other, and
wherein the alignment mark is formed on an area on which the first area and the second area overlap each other.

18. The method of claim 16, wherein the first pattern and the alignment mark are concurrently formed by one photomask.

19. The method of claim 16, wherein, in the aligning of the exposure module, the first area and the second area are aligned with each other in a first direction by using the alignment mark.

20. The method of claim 19, wherein a length of the first area and a length of the second area in the first direction are substantially the same.

21. The method of claim 19, wherein the mask sheet further comprises a third area spaced apart from the second area and partially overlapping the first area,
wherein the method further comprises performing, through the exposure module, a third exposure process on the third area to form a third pattern on the third area,
wherein a length of the first area in a first direction is greater than that of second area or the third area in the first direction.

22. The method of claim 21, further comprising, before the forming of the third pattern on the third area, aligning the exposure module with the third area,
wherein the alignment mark comprises:
a first alignment mark formed on an area of the first area that overlaps the second area; and
a second alignment mark formed on an area of the first area that overlaps the third area.

23. The method of claim 16, wherein the alignment mark comprises one of a plurality of circular patterns arranged in a first direction, a plurality cross-shaped patterns, and a bar-shaped pattern extending in the first direction.
